(19) United States
(12) Patent Application Publication
(10) Pub. No.: US 2017/0067593 A1
(43) Pub. Date: Mar. 9, 2017

(54) TRANSPARENT HEAT-SHIELDING/HEAT-INSULATING MEMBER AND PRODUCTION METHOD THEREOF

(71) Applicant: HITACHI MAXELL, LTD., Osaka (JP)

(72) Inventors: Yoshimasa MITSUMOTO, Osaka (JP); Teruhisa MIYATA, Osaka (JP)

(73) Assignee: HITACHI MAXELL, LTD., Osaka (JP)

(21) Appl. No.: 15/258,718

(22) Filed: Sep. 7, 2016

(30) Foreign Application Priority Data
Sep. 8, 2015 (JP) 2015-176975

(51) Int. Cl. F16L 59/02; C23C 14/14; C23C 14/08; C23C 14/00

(52) U.S. Cl. CPC F16L 59/028; C23C 14/0036; C23C 14/14; C23C 14/08; F16L 59/029

(57) ABSTRACT

A transparent heat-shielding/heat-insulating member 10 according to the present invention includes a transparent substrate 11 and a functional layer 23 formed on the transparent substrate 11. The functional layer 23 includes, from the transparent substrate 11 side, an infrared reflective layer 21 and a protective layer 22 in this order. The infrared reflective layer 21 includes, from the transparent substrate 11 side, at least a metal layer 13 and a metal suboxide layer 14 in which a metal is partially oxidized, in this order. The protective layer 22 has a total thickness of 200 to 980 nm and includes, from the infrared reflective layer 21 side, at least a high refractive index layer 17 and a low refractive index layer 18 in this order.

### BACKGROUND OF THE INVENTION

1. Field of the Invention

The present invention relates to a transparent heat-shielding/heat-insulating member and a production method thereof.

2. Description of Related Art

From the viewpoint of preventing global warming and saving energy, blocking heat rays from sunlight (infrared rays) through the windows of buildings, shop windows, the windows of vehicles and the like is commonly performed to reduce the indoor temperature (Patent Document 1: JP 2014-170171 A). In addition, recently, from the viewpoint of saving energy, heat-shielding/heat-insulating members that have not only heat shielding properties that block heat rays that cause a temperature increase in summer, but also a heat-insulating function that suppresses the escape of heat from inside the room in winter and reduces the heating load have been proposed and are introduced into the market (Patent Document 2: JP 2014-141015 A, Patent Document 3: JP 2014-167617 A, Patent Document 4: JP 2008-105251).

Patent Document 1 discloses a transparent heat-shielding film that has an anti-reflection function and in which a hardcoat layer, an infrared absorbing layer, a high refractive index layer and a low refractive index layer are sequentially stacked on a transparent substrate. The transparent heat-shielding film disclosed in Patent Document 1 is a transparent heat-shielding film of infrared absorbing type that absorbs infrared rays entering from the outside, and therefore does not have a heat-insulating function that reflects far-infrared rays having a wavelength of 5 to 25 μm emitted from a heater toward the indoor side in winter.

Patent Document 2 discloses an infrared reflective stacked film in which a heat ray reflective layer and a hardcoat layer are stacked in order on a substrate, the heat ray reflective layer having a multilayer structure in which a thin metal film and a thin metal oxide film are alternately stacked. The stacked film disclosed in Patent Document 2 is an infrared reflective stacked film, and has a heat-insulating function that reflects infrared rays toward the indoor side. However, when the thickness of the hardcoat layer is reduced in order to suppress the absorption of infrared rays and allow the heat-insulating function to work, particularly the thickness of the hardcoat layer is reduced to several hundred nanometers, which overlaps the wavelength range of visible light (380 to 780 nm), even the presence of a slight variation in the thickness of the hardcoat layer produces a noticeable glittering phenomenon in the appearance called “iridescent phenomenon” caused by a multi-reflective interference between interfacial reflection at the hardcoat layer and interfacial reflection at the heat ray reflective layer, and also increases a change in the reflection color due to a change in the optical path length when viewed from a different angle, which may present a problem of appearance when it is used by being attached to a window or the like.

Patent Document 3 discloses an infrared reflective film in which an infrared reflective layer including a first metal oxide layer, a metal layer and a second metal oxide layer in this order; and a transparent protective layer composed of an organic layer are formed on a transparent film substrate in this order. The infrared reflective film disclosed in Patent Document 3 is of infrared reflective type, and has a heat-insulating function that reflects infrared rays toward the indoor side. However, if the thickness of the transparent protective layer is changed to 150 nm or less, which is smaller than the wavelength range of visible light, in order to suppress the iridescent phenomenon that occurs in the appearance, physical properties such as scratch resistance tend to decrease, and scratches are likely to be generated on the film surface at the time of the application of the film or while the film is used for a long period of time, which may present problems caused by the scratches such as poor appearance and corrosion.

Furthermore, Patent Document 4 discloses a transparent stacked film including a thin metal oxide film, a thin silver-based film, and a thin metal oxide film for preventing silver diffusion in this order on a transparent polymer film. The transparent stacked film disclosed in Patent Document 4 is a stacked film that has an infrared reflecting function and a heat-insulating function that reflects infrared rays toward the indoor side when used in a state in which an infrared reflective layer of the infrared reflective film is disposed as an outermost layer on the indoor side. However, when the stacked film disclosed in Patent Document 4 is used as an infrared reflective film, it is necessary to provide a protective layer for preventing scratches or the like on the outermost layer side. Nevertheless, since Patent Document 4 does not mention about such a protective layer, further studies are required to form an appropriate protective layer.

In an infrared reflective type heat-shielding film including an infrared reflective layer composed of a stack of a thin metal film and a thin metal oxide film as disclosed in Patent Documents 2 to 4, the thin metal film is generally formed from a low refractive index material having an excellent infrared reflecting function, and the thin metal oxide film is generally formed from a high refractive index material that has a refractive index of 1.7 or more and has a protection function for controlling the reflectance at a wavelength in the visible light region so as to increase the visible light transmittance and for suppressing migration of metals in the thin metal film, while maintaining the infrared reflecting function of the thin metal film.

In the infrared reflective layer composed of a stack of a thin metal film and a thin metal oxide film, silver is often used as a thin metal film because silver has an excellent infrared reflecting function and does not substantially absorb the visible light. However, it is known that silver is easily corroded by the influence of moisture in the air etc., and for the purpose of controlling the reflectance at a wavelength in the visible light region so as to increase the visible light transmittance and for suppressing migration of metals in the thin metal film while maintaining the infrared reflecting function of the thin metal film as described above, the thin metal oxide film is stacked on the thin metal film. As the material of the thin metal oxide film, from the viewpoint of the transparency in visible light region and the reflective performance in the infrared reflective region, it is generally preferable to use a material having a high refractive index such as indium tin oxide (ITO). As can be seen from the foregoing, by stacking the thin metal oxide film on the thin metal film, it is possible to suppress the corrosion of the thin metal film to a certain level. However, for example, ITO has chemical stability that is not always sufficiently high, and depending on a long-term use environment, it cannot adequately suppress the corrosion or the like of a thin silver film by the influence of moisture in the air etc., and the corrosion of silver may be caused, which may present problems of the degradation of infrared reflecting function due to a decrease in transparency.

As explained in connection with Patent Document 2 and 4 above, for the purpose of suppressing the corrosion of a thin metal film, it has been known that the corrosion control effect of metal can be provided by stacking a metal partial oxide layer in which a metal is partially oxidized, or by stacking a barrier layer made of a thin film called a “metal suboxide layer” on one or both surface of the thin metal film.

In addition, when a UV-curable hardcoat layer made of an acrylic-based resin having a refractive index of, for example, around 1.5, which is usually used as a protective layer, is formed on the infrared reflective layer composed of a stack of a thin metal film and a thin metal oxide film, a multi-reflective interference occurs at each interface due to the difference in refractive index between each layer of the infrared reflective layer and the hardcoat layer and the thickness of each layer. As a result, the reflectance at each wavelength of visible light incident on the infrared reflective film varies significantly. That is, when a visible light reflection spectrum of the infrared reflective film is measured, a reflectance curve having a so-called “ripple”, which is a shape with significant fluctuations of peaks (maximum reflectance value) and valleys (minimum reflectance value), is observed.

Normally, a protective layer, such as a UV-curable hardcoat layer made of an acrylic-based resin is applied and formed by a wet coating method, and it is practically difficult to uniformly coat the entire surface of a substrate with the protective layer without any variation in the thickness of the layer (thickness variation). It is therefore impossible to completely eliminate the thickness variation caused by the influence of non-uniform drying, non-uniform application, the surface condition of the substrate, or the like. The thickness variation of the protective layer appears as deviations of peaks and valleys in the wavelength in the visible light reflection spectrum of the infrared reflective film, and in particular, causes the generation of an iridescent pattern when the thickness of the protective layer is reduced to several hundred nanometers.

When the thickness of the protective layer is increased to a thickness as thick as, for example, several microns, the interval between peaks and valleys decreases in the visible light reflection spectrum of the infrared reflective film, and even if there is some variation in the thickness of the protective layer, it is difficult to distinctively recognize the reflection color at a specific wavelength with the human eyes, and it is therefore almost not possible to perceive an iridescent pattern. Accordingly, the problem of appearance is unlikely to occur. However, the UV-curable hardcoat agent made of an acrylic-based resin used for the protective layer contains, in its molecular backbone, a large number of C═O groups, C—O groups and aromatic groups. For this reason, the UV-curable hardcoat agent made of an acrylic-based resin easily absorbs far-infrared rays having a wavelength of 5 to 25 μm, and the heat insulation properties of the infrared reflective film tend to decrease.

Accordingly, in order to cause the infrared reflective film to have sufficient heat insulation properties (for example, a normal emissivity value of 0.22 or less, and a heat transmission coefficient value of 4.2 W/m²·K or less), the thickness of the protective layer including the UV-curable hardcoat agent including an acrylic-based resin as a main component can be reduced to about 1.0 μm or less so as to suppress the absorption of far-infrared rays having a wavelength of 5 to 25 μm as much as possible. However, as explained in connection with Patent Document 2 above, when the thickness of the protective layer is reduced to several hundred nanometers, which overlaps the wavelength range of visible light, the interval between peaks and valleys increases in the visible light reflection spectrum of the infrared reflective film, and the reflection color at a specific wavelength can be recognized with the human eyes. Accordingly, even if there is a slight variation in the thickness of the protective layer, it is recognized as the iridescent phenomenon. In addition, a change in the reflection color due to a change in the optical path length when viewed from a different angle is also readily perceived, which may present a problem of appearance when it is used by being attached to a window or the like.

Furthermore, as explained in connection with Patent Document 3 above, when the thickness of the protective layer is changed to 150 nm or less, which is smaller than the wavelength range of visible light, the interval between peaks and valleys further increases in the visible light reflection spectrum of the infrared reflective film, and a reflectance curve having almost only one valley is obtained, and a uniform color is observed as an interference reflection color, and thus the problem of appearance is unlikely to occur. However, the scratch resistance tends to decrease, and thus scratches are likely to be generated on the film surface at the time of the application of the film or while the film is used for a long period of time, which still may present problems caused by the scratches such as poor appearance and corrosion.

As can be seen from the foregoing, it has been difficult to provide a transparent heat-shielding/heat-insulating member that achieves both an excellent heat shielding performance in summer and an excellent heat insulation performance in winter, and that has excellent scratch resistance and an excellent appearance that suppresses a reflection color change caused by the iridescent phenomenon and the viewing angle, and can maintain excellent corrosion resistance over a long-term use.

The present invention has been made to solve the problem described above, and provides a transparent heat-shielding/heat-insulating member excellent in durability, optical properties, scratch resistance and appearance by forming the infrared reflective layer using a specific material, and forming, on the infrared reflective layer, a protective layer having a stacked layer configuration with an appropriate film thickness.

### SUMMARY OF THE INVENTION

As a result of intensive studies conducted by the present inventors to solve the problem described above, the present inventors found that by providing a protective layer having a stacked layer configuration with an appropriate film thickness on an infrared reflective layer formed of a specific metal and a metal suboxide material in which a metal is partially oxidized, it is possible to obtain a transparent heat-shielding/heat-insulating member that has excellent physical properties such as film scratch resistance while maintaining the heat insulation properties, as well as an excellent appearance that suppresses the iridescent phenomenon and a reflection color change caused by the viewing angle, and the present invention has been accomplished.

A transparent heat-shielding/heat-insulating member according to the present invention is a transparent heat-shielding/heat-insulating member including a transparent substrate and a functional layer formed on the transparent substrate. The functional layer includes, from the transparent substrate side, an infrared reflective layer and a protective layer in this order. The infrared reflective layer includes, from the transparent substrate side, at least a metal layer and a metal suboxide layer in which a metal is partially oxidized, in this order. The protective layer has a total thickness of 200 to 980 nm and includes, from the infrared reflective layer side, at least a high refractive index layer and a low refractive index layer in this order.

A method for producing a transparent heat-shielding/heat-insulating member according to the present invention includes: forming an infrared reflective layer on a transparent substrate by a dry coating method; and forming a protective layer on the infrared reflective layer by a wet coating method.

According to the present invention, it is possible to provide a transparent heat-shielding/heat-insulating member that has an excellent corrosion resistance, i.e., durability, and that has an excellent heat-shielding function and heat-insulating function and that suppresses the iridescent phenomenon and a reflection color change caused by the viewing angle in the appearance.

### BRIEF DESCRIPTION OF THE DRAWINGS

FIG. 1 is a schematic cross-sectional view showing an example of a transparent heat-shielding/heat-insulating member according to the present invention.

FIG. 2 is a schematic cross-sectional view showing another example of a transparent heat-shielding/heat-insulating member according to the present invention.

FIG. 3 is a schematic cross-sectional view showing further another example of a transparent heat-shielding/heat-insulating member according to the present invention.

FIG. 4 is a diagram showing a reflection spectrum of a transparent heat-shielding/heat-insulating member of Example 1.

FIG. 5 is a diagram showing a reflection spectrum of a transparent heat-shielding/heat-insulating member of Comparative Example 1.

### DETAILED DESCRIPTION OF THE INVENTION

A transparent heat-shielding/heat-insulating member according to the present invention includes a transparent substrate and a functional layer formed on the transparent substrate. The functional layer includes, from the transparent substrate side, an infrared reflective layer and a protective layer in this order. The infrared reflective layer includes, from the transparent substrate side, at least a metal layer and a metal suboxide layer in which a metal is partially oxidized in this order. The protective layer has a total thickness of 200 to 980 nm and includes, from the infrared reflective layer side, at least a high refractive index layer and a low refractive index layer in this order.

With the configuration described above, the transparent heat-shielding/heat-insulating member according to the present invention has excellent durability and suppresses the iridescent phenomenon in the appearance, undergoes little color change by the viewing angle (low viewing angle dependence), and has an excellent heat-shielding function and heat-insulating function.

Hereinafter, a transparent heat-shielding/heat-insulating member according to the present invention will be described with reference to the drawings.

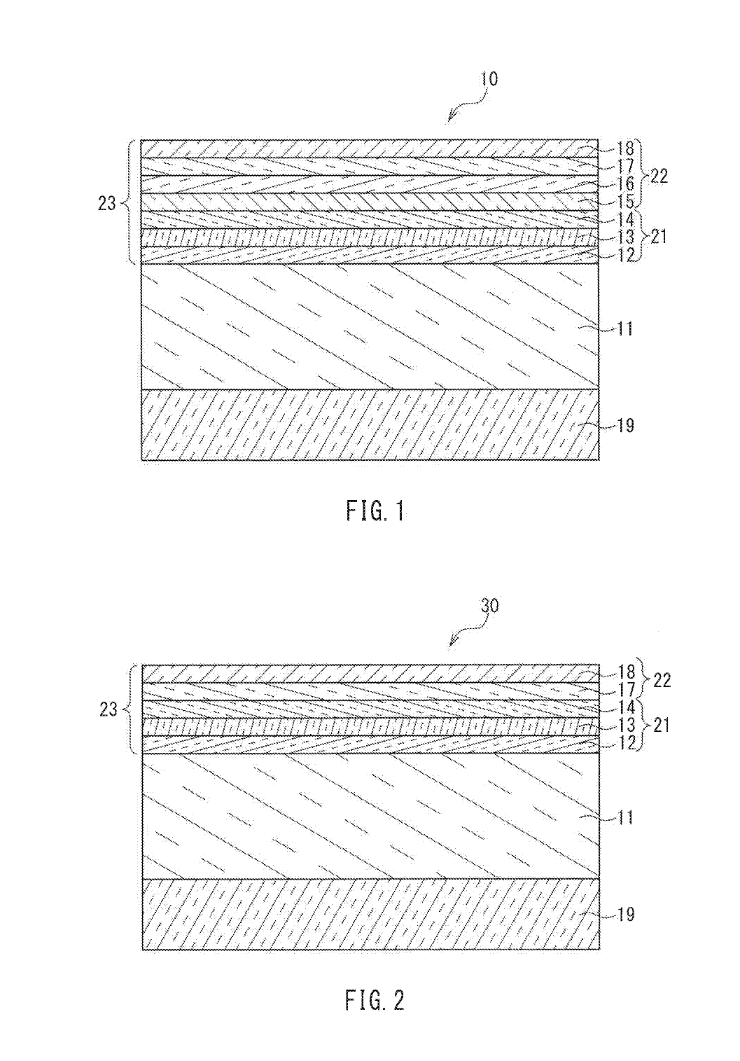

FIG. 1 is a schematic cross-sectional view showing an example of a transparent heat-shielding/heat-insulating member according to the present invention. In FIG. 1, a transparent heat-shielding/heat-insulating member 10 according to the present invention includes a transparent substrate 11, a functional layer 23 composed of an infrared reflective layer 21 and a protective layer 22, and a pressure-sensitive adhesive layer 19. The infrared reflective layer 21 includes, from the transparent substrate side, a metal suboxide layer 12, a metal layer 13, and a metal suboxide layer 14. The protective layer 22 includes an optical adjustment layer 15, a medium refractive index layer 16, a high refractive index layer 17, and a low refractive index layer 18.

FIG. 2 is a schematic cross-sectional view showing another example of a transparent heat-shielding/heat-insulating member according to the present invention. In FIG. 2, a transparent heat-shielding/heat-insulating member 30 according to the present invention has the same configuration as the configuration of the transparent heat-shielding/heat-insulating member 10 shown in FIG. 1 except that the protective layer 22 includes the high refractive index layer 17 and the low refractive index layer 18. In other words, the transparent heat-shielding/heat-insulating member 30 shown in FIG. 2 is obtained by changing the protective layer 22 of the transparent heat-shielding/heat-insulating member 10 shown in FIG. 1 to have a two-layer structure.

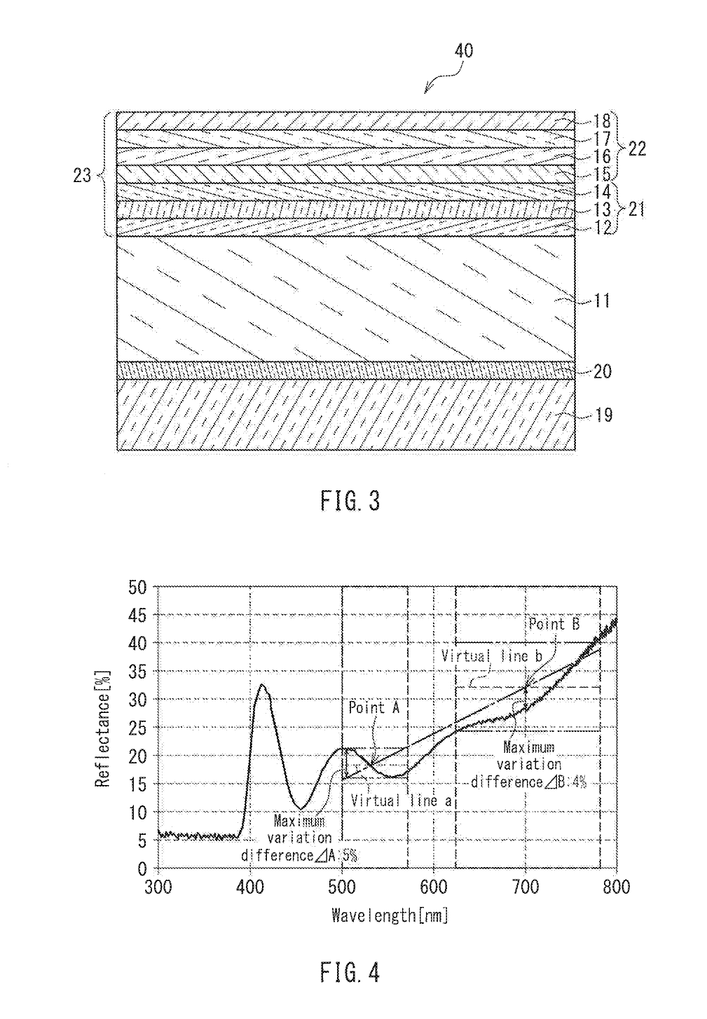

FIG. 3 is a schematic cross-sectional view showing further another example of a transparent heat-shielding/heat-insulating member according to the present invention. In FIG. 3, a transparent heat-shielding/heat-insulating member 40 according to the present invention has the same configuration as the configuration of the transparent heat-shielding/heat-insulating member 10 shown in FIG. 1 except that a cholesteric liquid crystal polymer layer 20 is disposed between a transparent substrate 11 and a pressure-sensitive adhesive layer 19. In other words, the transparent heat-shielding/heat-insulating member 40 shown in FIG. 3 is obtained by further including the cholesteric liquid crystal polymer layer 20 between the transparent substrate 11 and the pressure-sensitive adhesive layer 19 of the transparent heat-shielding/heat-insulating member 10 shown in FIG. 1.

Hereinafter, each constituent member of the transparent heat-shielding/heat-insulating member according to the present invention will be described.

<Transparent Substrate>

There is no particular limitation on the transparent substrate that constitutes the transparent heat-shielding/heat-insulating member according to the present invention as long as it is made of a light transmitting material. As the transparent substrate, it is possible to use a film or sheet formed from, for example, a resin such as a polyester-based resin (for example, polyethylene terephthalate, polyethylene naphthalate or the like), a polycarbonate-based resin, a polyacrylic acid ester-based resin (for example, polymethyl methacrylate or the like), an alicyclic polyolefin-based resin, a polystyrene-based resin (for example, polystyrene, an acrylonitrile-styrene copolymer or the like), a polyvinyl chloride-based resin, a polyvinyl acetate-based resin, a polyethersulfone-based resin, a cellulose-based resin (for example, diacetyl cellulose, triacetyl cellulose or the like), or a norbornene-based resin. As the method for forming the resin into a film or sheet, it is possible to use an extrusion method, a calendering method, a compression molding method, an injection molding method, a method in which the above resin is dissolved in a solvent and thereafter subjected to casting, or the like. The resin may further contain additives such as an antioxidant, a flame retardant, a heat stabilizer, an ultraviolet absorbing agent, a lubricant, and an anti-static agent. The thickness of the transparent substrate is, for example, 10 to 500 μm, and is preferably 25 to 125 μm, considering the processability and the cost.

<Infrared Reflective Layer>

The infrared reflective layer that constitutes the transparent heat-shielding/heat-insulating member according to the present invention includes, from the transparent substrate side, at least a metal layer made of a metal such as silver, copper, gold or aluminum, and a metal suboxide layer in which a metal is partially oxidized, in this order. Examples of the layer configuration include (1) a transparent substrate, a metal layer, and a metal suboxide layer, and (2) a transparent substrate, a metal layer, a metal suboxide layer, a metal layer, and a metal suboxide layer, respectively in this order. A metal suboxide layer in which a metal is partially oxidized, or a metal oxide layer may be provided between the transparent substrate and the metal layer. Examples of the layer configuration include (1) a transparent substrate, a metal suboxide layer, a metal layer, and a metal suboxide layer, (2) a transparent substrate, a metal suboxide layer, a metal layer, a metal suboxide layer, a metal layer, and a metal suboxide layer, (3) a transparent substrate, a metal oxide layer, a metal layer, and a metal suboxide layer, (4) a transparent substrate, a metal oxide layer, a metal layer, a metal suboxide layer, a metal layer, and a metal suboxide layer, respectively in this order. Among them, in terms of improving visible light transmittance and preventing corrosion of the metal layer, as the infrared reflective layer, it is preferable to include a layer configuration in which a metal layer is sandwiched between metal suboxide layers, or a layer configuration in which a metal layer is sandwiched between a metal oxide layer and a metal suboxide layer. By providing the infrared reflective layer, it is possible to impart heat-shielding function and heat-insulating function to the transparent heat-shielding/heat-insulating member of the present invention. A hardcoat layer or an adhesion promotion layer may be provided between the infrared reflective layer and the transparent substrate.

As the constituent material of the metal layer, metal materials such as silver (refractive index n=0.12), copper (n=0.95), gold (n=0.35) and aluminum (n=0.96) can be used as appropriate. Among them, from the viewpoint of small absorption of visible light, it is preferable to use silver. For the purpose of improving corrosion resistance, it is also possible to use an alloy containing at least one or more of palladium, gold, copper, aluminum, bismuth, nickel, niobium, magnesium, zinc and the like. The metal layer can be formed by forming the above material into a film by a dry coating method such as a sputtering method or a vapor deposition method. Each metal layer may have a thickness of 3 to 20 nm per layer.

The metal suboxide layer means a partial (incomplete) oxide layer which has the oxygen element content smaller than that of the complete oxide according to stoichiometric composition of the metal. By providing the metal suboxide layer on the metal layer, it is possible to improve visible light transmittance of the infrared reflective layer and to prevent corrosion of the metal layer. As the constituent material of the metal suboxide layer, it is possible to use, as appropriate, a metal partial oxide material in which a metal such as titanium, nickel, chromium, cobalt, indium, tin, niobium, zirconium, zinc, tantalum, aluminum, cerium, magnesium, silicon, and mixtures thereof is partially oxidized. Among them, as the metal suboxide layer, it is preferable to use a titanium metal partial oxide layer or a metal partial oxide layer including a titanium as a main component, because they are dielectrics relatively transparent with respect to visible light and have a high refractive index. In other words, the metal suboxide layer preferably contains a titanium component.

Although there is no particular limitation on the method for forming the metal suboxide layer, for example, the metal suboxide layer can be formed by a reactive sputtering method. In other words, at the time of forming a film by the sputtering method using a target made of the above metals, by adding an oxygen gas having an appropriate concentration to an atmospheric gas that contains an inert gas such as an argon gas, it is possible to form a metal partial (incomplete) oxide layer, i.e., the metal suboxide layer containing oxygen elements based on the concentration of the oxygen gas. It is also possible to from the metal partial (incomplete) oxide layer by forming a thin metal film or a partially oxidized thin metal film by the sputtering method etc., and thereafter performing after-oxidization such as a heat treatment or the like.

As the constituent material of the metal oxide layer that is disposed under the metal layer, it is possible to use, as appropriate, metal oxide materials such as indium tin oxide (refractive index n=1.92), indium zinc oxide (n=2.00), indium oxide (n=2.00), titanium oxide (n=2.50), tin oxide (n=2.00), zinc oxide (n=2.03), niobium oxide (n=2.30), aluminum oxide (n=1.77), and the like. The metal oxide layer can be formed by forming the above material into a film by, for example, a dry coating method such as a sputtering method, a vapor deposition method, or an ion plating method.

As the infrared reflective layer, when the layer configuration in which the metal layer is sandwiched between the metal suboxide layers (a metal suboxide layer [upper], a metal layer, and a metal suboxide layer [lower]) is applied, each of the metal suboxide layer may be formed into a film from the same metal material, or formed into a film from the different metal material. It is preferable that the metal suboxide layer formed on at least the metal layer is formed of a titanium metal partial oxide layer or a metal suboxide layer including a titanium as a main component. It is thereby possible to prevent corrosion of the metal layer and improve adhesion to the protective layer that is provided on the infrared reflective layer.

As the infrared reflective layer, when the layer configuration in which the metal layer is sandwiched between the metal suboxide layer and the metal oxide layer (a metal suboxide layer [upper], a metal layer, and a metal oxide layer [lower]) is applied, it is preferable to have the same aspect as that described above.

When the metal suboxide layer is formed of a metal (TiOₓ) suboxide layer of a titanium (Ti) metal, from the viewpoint of a balance between visible light transmittance of the infrared reflective layer and the corrosion suppression of the metal layer, x of the TiOₓ in the layer is preferably set to 0.5 or more and less than 2.0. If the x of the TiOₓ is less than 0.5, the corrosion resistance of the metal layer can be improved, however, the visible light transmittance of the infrared reflective layer may be reduced. If the x of the TiOₓ is 2.0 or more, the visible light transmittance of the infrared reflective layer can be increased, however, the corrosion resistance of the metal layer may be reduced. The x of the TiOₓ can be analyzed and calculated using an energy-dispersive fluorescent X-ray analyzer (EDX) or the like.

The metal suboxide layer preferably has a thickness of 1 to 8 nm. If the thickness is within the range described above, sufficient corrosion suppression effect of the metal layer can be achieved. On the other hand, if the thickness is less than 1 nm, it is difficult to achieve the corrosion suppression effect of the metal layer. If the thickness is more than 8 nm, the improvement effect of corrosion resistance of the metal layer tends to be saturated, and the influence caused by the absorption of light of the metal suboxide layer increases, or the visible light transmittance of the infrared reflective layer may be reduced, and processing speed of the sputtering at the time of forming a film may be reduced, thereby reducing the productivity.

The metal suboxide layer that is disposed under the metal layer preferably has a thickness of 2 to 80 nm. If the thickness is less than 2 nm, effect of the layer as a light compensation layer to the metal layer is insufficient, and the improvement effect of visible light transmittance of the infrared reflective layer may be reduced, and the corrosion suppression effect of the metal layer may not be achieved. In contrast, if the thickness is more than 80 nm, the further effect of the layer as a light compensation layer to the metal layer cannot be achieved, and the improvement effect of visible light transmittance of the infrared reflective layer may gradually decrease conversely, and processing speed of the sputtering at the time of forming a film may be reduced, thereby reducing the productivity.

Each of the metal oxide layer and the metal suboxide layer preferably has a refractive index of 1.7 or more, and more preferably 1.8 or more, and even more preferably 2.0 or more.

The infrared reflective layer is preferably set to have an average far-infrared light reflectance at a wavelength of 5.5 to 25.2 μm of 80% or more, more preferably 85% or more, and even more preferably 90% or more. It is thereby possible to, even when a protective layer described later is formed on the transparent heat-shielding/heat-insulating member according to the present invention, adjust a normal emissivity to be 0.22 or less (a heat transmission coefficient value of 4.2 W/m²·K or less), and reliably impart a heat-insulating function to the transparent heat-shielding/heat-insulating member.

As specified in Japanese Industrial Standards (JIS) R3106-2008, a normal emissivity is represented by the following formula:

Normal emissivity (∈ₙ)=1−spectral reflectance (ρₙ)

The spectral reflectance ρₙ is measured at a wavelength of 5.5 to 50 μm that is a wavelength range of heat radiation at a normal temperature. The wavelength range of 5.5 to 50 μm is in the far-infrared region, and thus, when the reflectance in the wavelength range of the far-infrared rays increases higher, the normal emissivity reduces accordingly, and excellent heat insulation properties are obtained.

<Protective Layer>

The protective layer that constitutes the transparent heat-shielding/heat-insulating member according to the present invention includes, from the infrared reflective layer side, at least a high refractive index layer and a low refractive index layer in this order, and is set to have a total thickness of 200 to 980 nm. By providing the protective layer, it is possible to impart scratch resistance and corrosion resistance, i.e., durability to the transparent heat-shielding/heat-insulating member according to the present invention, without causing a reduction in heat insulation performance, and can improve the appearance.

The protective layer preferably includes, from the infrared reflective index layer side, a medium refractive index layer, a high refractive index layer and a low refractive index layer in this order, and mostly preferably includes, from the infrared reflective layer side, an optical adjustment layer, a medium refractive index layer, a high refractive index layer and a low refractive index layer in this order.

The protective layer is set to have a total thickness of 200 to 980 nm. If the total thickness is less than 200 nm, physical properties such as scratch resistance and corrosion resistance may be reduced. If the total thickness is more than 980 nm, the absorption of infrared rays increases and normal emissivity increases, which may lead to a reduction in the heat insulation properties, and thus such a thickness is not preferable. If the total thickness is within a range of 200 to 980 nm, a normal emissivity measured based on JIS R3106-1998 of 0.22 or less (a heat transmission coefficient value of 4.2 W/m²·K or less) is attained on the functional layer side, and a sufficient heat insulation performance can be achieved. From the viewpoint of a further improvement in scratch resistance, the protective layer is preferably set to have a total thickness of 300 nm or more, and from the viewpoint of a further decrease in normal emissivity, the protective layer is preferably set to have a total thickness of 700 nm or less, of 300 to 700 nm. If the total thickness is within a range of 300 to 700 nm, a normal emissivity measured based on JIS R3106-1998 of 0.17 or less (a heat transmission coefficient value of 4.0 W/m²·K or less) is attained on the functional layer side, and both heat insulation performance and scratch resistance can be achieved at a further higher level.

It is required that the combination of refractive index or thickness of each layer that constitutes the protective layer is to be designed so that the size of a so-called ripple in a visible light reflection spectrum of the transparent heat-shielding/heat-insulating member according to the present invention is reduced, and for that reason, each layer of the protective layer needs to be adjusted by combining optimal refractive index or thickness within a total thickness of the protective layer of 200 to 980 nm, so as to achieve a desired optical characteristic.

Hereinafter, each layer that constitutes the protective layer will be described.

Optical Adjustment Layer

The optical adjustment layer is a layer for adjusting optical characteristics of the infrared reflective layer of the transparent heat-shielding/heat-insulating member according to the present invention, and is preferably set to have a refractive index at a wavelength of 550 nm of 1.60 to 2.00, and more preferably 1.65 to 1.90. It is difficult to generalize the thickness of the optical adjustment layer because the appropriate range can vary depending on the refractive index or thickness of each of a medium refractive index layer, a high refractive index layer and a low refractive index layer that are stacked on the optical adjustment layer in this order. However, in consideration of a balance with the configuration of other layers described above, the optical adjustment layer is preferably set to have a thickness of 30 to 80 nm, and more preferably 35 to 70 nm. By setting the thickness of the optical adjustment layer within a range of 30 to 80 nm, visible light reflectance of the transparent heat-shielding/heat-insulating member according to the present invention can be reduced and transparency, i.e., visible light transmittance can be further improved.

As the constituent material of the optical adjustment layer, it is preferable to contain a material of the same kind as the material constituting the metal suboxide layer of the infrared reflective layer, in terms of securing adhesion to the metal suboxide layer that directly contacts with the optical adjustment layer. For example, when a titanium metal partial oxide layer or a metal partial oxide layer including a titanium as a main component is selected as the metal suboxide layer, it is preferable that the constituent material of the optical adjustment layer is a material containing titanium oxide fine particles. The inclusion of the titanium oxide fine particles in the constituent material of the optical adjustment layer enables appropriate control of the refractive index of the optical adjustment layer within a range of 1.60 to 2.00 at a high level, and in addition, the adhesion to the titanium metal partial oxide layer or the metal partial oxide layer including a titanium as a main component can be increased.

There is no particular limitation on the constituent material of the optical adjustment layer containing the inorganic fine particles represented by the titanium oxide fine particles as long as the refractive index of the optical adjustment layer can be set within the range described above, for example, a material containing a resin such as a thermoplastic resin, a thermosetting resin, and an ionizing radiation curable resin, and inorganic fine particles dispersed in the resin are preferably used. Among the constituent materials of the optical adjustment layer listed above, in terms of optical characteristics such as transparency, physical properties such as scratch resistance, and further productivity, it is preferable to use a material containing the ionizing radiation curable resin and the inorganic fine particles dispersed in the ionizing radiation curable resin. In general, the material containing the ionizing radiation curable resin and the inorganic fine particles included therein is applied on the metal suboxide layer, and thereafter irradiated with ionizing radiation such as ultraviolet rays to cure the layer, thereby forming the optical adjustment layer. Since the material contains inorganic fine particles, the shrinkage of a film at the time of curing is suppressed, and thus excellent adhesion between the optical adjustment layer and the metal suboxide layer can be achieved.

Examples of the thermoplastic resin include a modified polyolefin-based resin, a vinyl chloride-based resin, an acrylonitrile-based resin, a polyamide-based resin, a polyimide-based resin, a polyacetal-based resin, a polycarbonate-based resin, a polyvinyl butyral-based resin, an acrylic-based resin, a polyvinyl acetate-based resin, a polyvinyl alcohol-based resin, and a cellulose-based resin. Examples of the thermosetting resin include a phenol-based resin, a melamine-based resin, an urea-based resin, an unsaturated polyester-based resin, an epoxy-based resin, a polyurethane-based resin, a silicone-based resin, and an alkyd-based resin. These can be used alone or in combination. The optical adjustment layer can be formed by adding a crosslinking agent if necessary, followed by heat curing.

Examples of the ionizing radiation curable resin include, for example, a multifunctional (meth)acrylate monomer having two or more unsaturated groups and a multifunctional (meth)acrylate oligomer (prepolymer). These can be used alone or in combination. Specific examples include: acrylates such as ethylene glycol di(meth)acrylate, diethylene glycol di(meth)acrylate, triethylene glycol di(meth)acrylate, 1,4-cyclohexanediacrylate, pentaerythritol tetra(meth)acrylate, pentaerythritol tri(meth)acrylate, trimethylolpropane tri(meth)acrylate, trimethylolethane tri(meth)acrylate, dipentaerythritol tetra(meth)acrylate, dipentaerythritol penta(meth)acrylate, dipentaerythritol hexa(meth)acrylate, and 1,2,3-cyclohexane trimethacrylate; vinylbenzenes such as 1,4-divinylbenzene, 4-vinyl benzoic acid-2-acryloyl ethyl ester and 1,4-divinyl cyclohexanone, and derivatives thereof, urethane-based multifunctional acrylate oligomers such as pentaerythritol triacrylate hexamethylene diisocyanate urethane prepolymer; ester-based multifunctional acrylate oligomers produced from a polyhydric alcohol and a (meth)acrylic acid; and epoxy-based multifunctional acrylate oligomers. The optical adjustment layer can be formed by adding a photopolymerization initiator if necessary, followed by irradiation with ionizing radiation to cure the layer.

In order to further improve the adhesion between the optical adjustment layer containing the ionizing radiation curable resin, and the metal suboxide layer of the infrared reflective layer, the ionizing radiation curable resin may contain a (meth)acrylic acid derivative having a polar group such as a phosphoric acid group, a sulfonic acid group, and an amide group, and a silane coupling agent having an unsaturated group such as a (meth)acryl group, and a vinyl group, and used.

The inorganic fine particles are added and dispersed in the resin for adjusting the refractive index of the optical adjustment layer. As the inorganic fine particles, it is possible to use titanium oxide (TiO₂), zirconium oxide (ZrO₂), zinc oxide (ZnO), indium tin oxide (ITO), niobium oxide (Nb₂O₅), yttrium oxide (Y₂O₃), indium oxide (In₂O₃), tin oxide (SnO₂), antimony oxide (Sb₂O₃), tantalum oxide (Ta₂O₅), tungsten oxide (WO₃), and the like. The inorganic fine particles may be subjected to a surface treatment by a dispersant if necessary. Among the inorganic fine particles listed above, it is preferable to use titanium oxide and zirconium oxide in terms of higher refractive index attained by a smaller adding amount thereof as compared with other materials, and it is more preferable to use titanium oxide in terms of relatively small absorption of light in the infrared region, and in terms of securing the adhesion to a TiOₓ layer that is suitable for the metal suboxide layer.

As the particle size of the inorganic fine particles, from the viewpoint of transparency of the optical adjustment layer, the inorganic fine particles preferably have an average particle size of 5 to 100 nm, and more preferably 10 to 80 nm. If the average particle size is more than 100 nm, the haze value increases in the formed optical adjustment layer, which is likely to cause a reduction in the transparency. If the average particle size is less than 5 nm, it is difficult to maintain dispersion stability of the inorganic fine particles when used in an optical adjustment coating material.

Medium Refractive Index Layer

The medium refractive index layer is preferably set to have a light refractive index at a wavelength of 550 nm of 1.45 to 1.55, and more preferably 1.47 to 1.53. It is difficult to generalize the thickness of the medium refractive index layer because the appropriate range can vary depending on the refractive index or thickness of each of an optical adjustment layer that is formed under the medium refractive layer; and a high refractive index layer and a low refractive index layer that are formed on the medium refractive index layer in this order. However, in consideration of a balance with the configuration of other layers described above, the medium refractive index layer is preferably set to have a thickness of 40 to 200 nm, and more preferably 50 to 150 nm. If the thickness of the medium refractive index layer is less than 40 nm, it may lead to a reduction in the adhesion to the metal suboxide layer of the infrared reflective layer or the optical adjustment layer. If the thickness is more than 200 nm, the absorption of light in the infrared region may increase and heat insulation properties may be deteriorated, and thus such a thickness is not preferable. If the thickness is more than 200 nm, the size of ripple in the visible light reflection spectrum of the transparent heat-shielding/heat-insulating member, i.e., variation in reflectance to a wavelength in the visible light region cannot be reduced, which not only makes an iridescent pattern more noticeable, but also increases the reflection color change due to the viewing angle, which may present a problem of appearance.

There is no limitation on the constituent material of the medium refractive index layer as long as the refractive index of the medium refractive index layer can be set within the range described above, for example, a thermoplastic resin, a thermosetting resin, an ionizing radiation curable resin or the like are preferably used. As the resins such as the thermoplastic resin, the thermosetting resin, and the ionizing radiation curable resin, it is possible to use the same resins as those can be used for the optical adjustment layer described above, and the same method can be used to form the medium refractive index layer. The inorganic fine particles may be added and dispersed in the resin for adjusting the refractive index if necessary. Among the constituent materials of the medium refractive index layer listed above, in terms of optical characteristics such as transparency, physical properties such as scratch resistance, and further productivity, it is preferable to use a material containing the ionizing radiation curable resin.

Among the ionizing radiation curable resin, it is more preferable to use a resin containing an urethane-based multifunctional (meth)acrylate oligomer (pre-polymer), an ester-based multifunctional (meth)acrylate oligomer (pre-polymer), and an epoxy-based multifunctional (meth)acrylate oligomer (pre-polymer) having relatively slight curing shrinkage at the time of irradiation with ionizing radiation such as ultraviolet rays. With this configuration, the adhesion between the medium refractive index layer and the metal suboxide layer of the infrared reflective layer or the optical adjustment layer can be improved.

In order to further improve the adhesion between the medium refractive index layer containing the ionizing radiation curable resin and the metal suboxide layer of the infrared reflective layer or the optical adjustment layer, the ionizing radiation curable resin may contain a (meth)acrylic acid derivative having a polar group such as a phosphoric acid group, a sulfonic acid group, and an amide group, and a silane coupling agent having an unsaturated group such as a (meth)acryl group and a vinyl group, and used.

High Refractive Index Layer

The high refractive index layer is preferably set to have a light refractive index at a wavelength of 550 nm of 1.65 to 1.95, and more preferably 1.70 to 1.90. It is difficult to generalize the thickness of the high refractive index layer because the appropriate range can vary depending on the refractive index or thickness of each of a medium refractive index layer and an optical adjustment layer that are formed under the high refractive index layer in this order; and a low refractive index layer that is formed on the high refractive index layer. However, in consideration of a balance with the configuration of other layers described above, the high refractive index layer is preferably set to have a thickness of 60 to 550 nm, and more preferably 65 to 400 nm. If the thickness of the high refractive index layer is less than 60 nm, physical properties such as scratch resistance of the film surface may decrease. A thickness more than 550 nm is not preferable because, if the high refractive index layer contains a large amount of inorganic fine particles, the absorption of light in the infrared region increases, and normal emissivity increases, which may lead to a reduction in the heat insulation properties, and thus such a thickness is not preferable.

There is no particular limitation on the constituent material of the high refractive index layer as long as the refractive index of the high refractive index layer can be set within the range described above, it is preferable to use, for example, a material containing a resin such as a thermoplastic resin, a thermosetting resin, and an ionizing radiation curable resin and inorganic fine particles dispersed in the resin. As the resins such as the thermoplastic resin, the thermosetting resin, and the ionizing radiation curable resin and as the inorganic fine particles, it is possible to use the same resins and the same organic fine particles as those can be used for the optical adjustment layer described above, and the same method can be used to form the high refractive index layer. Among the constituent materials of the high reactive index layer listed above, in terms of optical characteristics such as transparency, physical properties such as scratch resistance, and further productivity, it is preferable to use a material containing the ionizing radiation curable resin and the inorganic fine particles dispersed in the ionizing radiation curable resin. In general, the material containing the ionizing radiation curable resin and the inorganic fine particles included therein is applied on the metal suboxide layer or the medium refractive index layer, and thereafter irradiated with ionizing radiation such as ultraviolet rays to cure the layer, thereby forming the high refractive index layer. Since the material contains inorganic fine particles, the shrinkage of a film at the time of curing is suppressed, and thus excellent adhesion between the high refractive index layer and the metal suboxide layer or the medium refractive index layer can be achieved.

The inorganic fine particles are added for adjusting the refractive index of the high refractive index layer. Among the inorganic fine particles, it is preferable to use titanium oxide and zirconium oxide in terms of a higher refractive index attained by a smaller adding amount thereof as compared with other materials, and it is more preferable to use titanium oxide in terms of relatively small absorption of light in the infrared region.

In order to further improve the adhesion between the high refractive index layer containing the ionizing radiation curable resin and the metal suboxide layer of the infrared reflective layer or the medium refractive index layer, the ionizing radiation curable resin may contain a (meth)acrylic acid derivative having a polar group such as a phosphoric acid group, a sulfonic acid group, and an amide group, and a silane coupling agent having an unsaturated group such as a (meth)acryl group and a vinyl group, and used.

Low Refractive Index Layer

The low refractive index layer preferably has a light refractive index at a wavelength of 550 nm of 1.30 to 1.45, and more preferably 1.35 to 1.43. It is difficult to generalize the thickness of the low refractive index layer because the appropriate range can vary depending on the refractive index or thickness of each of a high refractive index layer, a medium refractive index layer, and an optical adjustment layer that are formed under the low refractive index layer in this order. However, in consideration of a balance with the configuration of other layers described above, the low refractive index layer is preferably set to have a thickness of 70 to 150 nm, and preferably 80 to 130 nm. If the thickness of the low refractive index layer is outside the range of 70 to 150 nm, the size of ripple in a visible light reflection spectrum of the transparent heat-shielding/heat-insulating member according to the present invention, i.e., variation in reflectance to a wavelength in the visible light region cannot be reduced sufficiently, which not only makes an iridescent pattern more noticeable, but also increases the reflection color change due to the viewing angle, which may present a problem of appearance. In addition, the visible light transmittance may be reduced.

There is no particular limitation on the constituent material of the low refractive index layer as long as the refractive index of the low refractive index layer can be set within the range described above, for example, it is preferable to use a material containing a resin such as a thermosetting resin and an ionizing radiation curable resin and low refractive index inorganic fine particles dispersed in the resin, and a material containing an organic-inorganic hybrid material where an organic component and an inorganic component are chemically bonded. Among the constituent materials of the low refractive index layer listed above, in terms of optical characteristics such as transparency, physical properties such as scratch resistance, and further productivity, it is preferable to use a material containing the ionizing radiation curable resin and low refractive index inorganic fine particles dispersed in the ionizing radiation curable resin, and a material containing an organic-inorganic hybrid material where the ionizing radiation curable resin and low refractive index inorganic fine particles are chemically bonded.

As the ionizing radiation curable resin, the same resins as those can be used for the optical adjustment layer described above and a fluorine-based ionizing radiation curable resin can be used, and the same method can be used to form the low refractive index layer.

The inorganic fine particles are dispersed and added in the resin for adjusting the refractive index of the low refractive index layer. As the low refractive index inorganic fine particles, for example, silicon oxide, magnesium fluoride, aluminum fluoride or the like can be used. However, from the viewpoint of the physical properties such as scratch resistance of the low refractive index layer that is to be disposed as an outermost surface of the protective layer, it is preferable to use a silicon oxide-based material, and it is particularly preferable to use a hollow silicon oxide (hollow silica)-based material having pores inside, in order to attain a low refractive index.

In general, the material containing the ionizing radiation curable resin and the inorganic fine particles included therein is applied on the high refractive index layer, and thereafter irradiated with ionizing radiation such as ultraviolet rays to cure the layer, thereby forming the low refractive index layer. Since the material contains inorganic fine particles, the shrinkage of a film at the time of curing is suppressed, and thus excellent adhesion to the high refractive index layer can be achieved.

In order to further improve the adhesion between the low refractive index layer containing the ionizing radiation curable resin and the high refractive index layer, the ionizing radiation curable resin may contain a (meth)acrylic acid derivative having a polar group such as a phosphoric acid group, a sulfonic acid group, and an amide group, and a silane coupling agent having an unsaturated group such as a (meth)acryl group and a vinyl group, and used.

Other than the constituent materials listed above, the constituent material of the low refractive index layer may further contain additives such as a leveling agent, a fingerprint adhesion inhibitor, a lubricant, an anti-static agent, and a haze imparting agent. The amount of these additives may be adjusted as appropriate within a range that does not impair the purpose of the present invention.

As described above, when the protective layer adopts any of the following layer configurations: (1) layer configuration including, from the infrared reflective layer side, a high refractive index layer and a low refractive index layer in this order; (2) layer configuration including, from the infrared reflective layer side, a medium refractive index layer, a high refractive index layer and a low refractive index layer in this order; or (3) layer configuration including, from the infrared reflective layer side, an optical adjustment layer, a medium refractive index layer, a high refractive index layer and a low refractive index layer in this order, it is possible to provide a transparent heat-shielding/heat-insulating member that has excellent physical properties such as scratch resistance and corrosion resistance while maintaining the heat insulation properties (a normal emissivity measured based on JIS R3106-1998 of 0.22 or less, and a heat transmission coefficient value of 4.2 W/m²·K or less) as well as an excellent appearance that suppresses the iridescent phenomenon and a reflection color change caused by the viewing angle, by appropriately setting the thickness of each layer as follows:

the optical adjustment layer having a refractive index at a wavelength of 550 nm of 1.60 to 2.00 is set to have a thickness of 30 to 80 nm;

the medium refractive index layer having a refractive index at a wavelength of 550 nm of 1.45 to 1.55 is set to have a thickness of 40 to 200 nm;

the high refractive index layer having a refractive index at a wavelength of 550 nm of 1.65 to 1.95 is set to have a thickness of 60 to 550 nm; and

the low refractive index layer having a refractive index at a wavelength of 550 nm of 1.30 to 1.45 is set to have a thickness of 70 to 150 nm, so that the protective layer composed of a stack of each layer has a total thickness of 200 to 980 nm.

As a more preferable range, if the protective layer is set to have a total thickness of 300 to 700 nm, a normal emissivity measured based on JIS R3106-1998 of 0.17 or less (a heat transmission coefficient value of 4.0 W/m². K or less) is attained on the functional layer side, and adequate mechanical properties as a protective layer can be obtained and both sufficient heat insulation performance and scratch resistance can be achieved at a further higher level

<Cholesteric Liquid Crystal Polymer Layer>

In the transparent heat-shielding/heat-insulating member according to the present invention, a cholesteric liquid crystal polymer layer may be further formed on a surface of the transparent substrate on which the infrared reflective layer is not formed as long as transparency is not lost. With this configuration, the heat-shielding function of the transparent heat-shielding/heat-insulating member of the present invention can be further improved.

The cholesteric liquid crystal polymer layer can be formed by photopolymerization of a material containing a liquid crystal compound having a polymerizable functional group, a chiral agent having a polymerizable functional group and a multifunctional acrylate compound.

A cholesteric liquid crystal polymer can be obtained by adding a small amount of optically active compound (chiral agent) to a nematic liquid crystal compound containing rod-like molecules. The cholesteric liquid crystal polymer has a layered structure having alternating layers of a nematic liquid crystal compound. In each layer, the nematic liquid crystal compound is aligned in a certain direction, and the layers are accumulated such that a helical shape is formed in the alignment direction of the liquid crystal compound. Accordingly, the cholesteric liquid crystal polymer can selectively reflect only light having a specific wavelength according to the helical pitch.

A normal cholesteric liquid crystal polymer has a feature in that the helical pitch changes according to the temperature and the wavelength of reflected light changes. By making a mixture containing a liquid crystal compound having a polymerizable functional group and a chiral agent having a polymerizable functional group uniform in a liquid crystal state and thereafter irradiating the mixture with active energy rays such as ultraviolet rays while the liquid crystal state is maintained, it is possible to produce a layer containing a cholesteric liquid crystal polymer in which the alignment state of the liquid crystal compound is semi-permanently fixed.

With the cholesteric liquid crystal polymer layer obtained in the manner described above, the wavelength of reflected light does not change according to the temperature, and thus the reflection wavelength can be semi-permanently fixed. Also, the cholesteric liquid crystal polymer layer has a cholesteric liquid crystal optical rotation, and thus when the rotation direction and wavelength of circularly polarized light are equal to the rotation direction of liquid crystal molecules and the helical pitch, reflection takes place without passing through the light. Normally, sunlight is composed of right-handed circularly polarized light and left-handed circularly polarized light. Accordingly, by stacking a cholesteric liquid crystal polymer layer in which the direction of the optical rotation is set to a specific helical pitch by using a right-handed chiral agent and a cholesteric liquid crystal polymer layer in which the direction of the optical rotation is set to a specific helical pitch by using a left-handed chiral agent, the reflectance at a selective reflection wavelength can be further increased.

The thickness of the cholesteric liquid crystal polymer layer is preferably greater than or equal to 1.5 times and less than or equal to 4.0 times the wavelength at which incident light is reflected at a maximum (maximum reflectance wavelength), and is more preferably greater than or equal to 1.7 times and less than or equal to 3.0 times the maximum reflectance wavelength. If the thickness of the cholesteric liquid crystal polymer layer is less than 1.5 times the maximum reflectance wavelength, it is difficult to maintain the orientation of the cholesteric liquid crystal polymer layer, and the light reflectance may be reduced. If, on the other hand, the thickness of the cholesteric liquid crystal polymer layer is more than 4.0 times the maximum reflectance wavelength, although the orientation and light reflectance of the cholesteric liquid crystal polymer layer can be favorably maintained, the cholesteric liquid crystal polymer layer may be too thick. The thickness of the cholesteric liquid crystal polymer layer is, for example, 0.5 μm or more and 20 μm or less, and preferably 1 μm or more and 10 μm or less.

The structure of the cholesteric liquid crystal polymer layer is not limited to a mono-layer structure, and may be a multi-layer structure. The multi-layer structure is preferable because the layers have different selective reflection wavelengths and thereby the wavelength range in which light is reflected can be broadened.

Hereinafter, the material for forming the cholesteric liquid crystal polymer layer will be described in detail.

Liquid Crystal Compound Having Polymerizable Functional Group

A liquid crystal compound having a polymerizable functional group is used to form the cholesteric liquid crystal polymer layer. As the liquid crystal compound, a known compound can be used such as the one disclosed in, for example, in Chapter 8 of “Liquid Crystals—Fundamentals and Applications” by Shoichi Matsumoto and Ichiro Tsunoda, Kogyo Chosakai Publishing Co., Ltd.

Specific examples of the liquid crystal compound include compounds disclosed in, for example, JP 2012-6997 A, JP 2012-168514 A, JP 2008-217001 A, WO 95/22586, JP 2000-281629 A, JP 2001-233837 A, JP 2001-519317 T, JP 2002-533742 T, JP 2002-308832 A, JP 2002-265421 A, JP 2005-309255 A, JP 2005-263789 A, JP 2008-291218 A, JP 2008-242349 A, and the like.

The liquid crystal compound used to form the cholesteric liquid crystal polymer layer may be made of a single compound. However, if the orientation of the cholesteric liquid crystal polymer layer, when formed by using a single compound, is easily disturbed, a high melting point liquid crystal compound and a low melting point liquid crystal compound may be used in combination. In this case, it is preferable that the difference in melting point between the high melting point liquid crystal compound and the low melting point liquid crystal compound is 15° C. or more and 30° C. or less, and more preferably 20° C. or more and 30° C. or less.

In the case where the high melting point liquid crystal compound and the low melting point liquid crystal compound are used in combination as the liquid crystal compound, the high melting point liquid crystal compound preferably has a melting point that is greater than or equal to the glass transition temperature of the transparent substrate. If the liquid crystal compound has a low melting point, it has excellent compatibility and solubility with respect to the chiral agent and the solvent, but if the melting point is too low, the resultant transparent heat-shielding/heat-insulating member has poor heat resistance. For this reason, at least the high melting point liquid crystal compound is preferably set to have a melting point that is greater than or equal to the glass transition temperature of the transparent substrate.

As the combination of the high melting point liquid crystal compound and the low melting point liquid crystal compound, commercially available products can be used. Examples include a combination of “PLC 7700” (trade name, manufactured by ADEKA Corporation, melting point: 90° C.) and PLC 8100 (trade name, manufactured by ADEKA Corporation, melting point: 65° C.), a combination of “PLC 7700” (trade name, manufactured by ADEKA Corporation, melting point: 90° C.) and “PLC 7500” (trade name, manufactured by ADEKA Corporation, melting point: 65° C.), and a combination of “UCL-017A” (trade name, manufactured by DIC Corporation, melting point: 96° C.) and “UCL-017” (trade name, manufactured by DIC Corporation, melting point: 70° C.).

In the case where three or more compounds are used as the liquid crystal compound having a polymerizable functional group, the compound having the highest melting point is used as the high melting point liquid crystal compound, and the compound having the lowest melting point is used as the low melting point liquid crystal compound.

In the case where two or more compounds are used in combination as the liquid crystal compound having a polymerizable functional group, the proportion of the high melting point liquid crystal compound is preferably 90 mass % or less in the entire liquid crystal compound. If the proportion of the high melting point liquid crystal compound is more than 90 mass %, the compatibility of the liquid crystal compound tends to decrease, and as a result, the orientation of the cholesteric liquid crystal polymer layer may be partially disturbed, causing an increase in haze.

Chiral Agent Having Polymerizable Functional Group

There is no particular limitation on the structure of the chiral agent having a polymerizable functional group used to form the cholesteric liquid crystal polymer layer as long as the chiral agent has good compatibility with the liquid crystal compound and can be dissolved in a solvent, and a conventionally used chiral agent having a polymerizable functional group can be used.

Specific examples of the chiral agent include compounds disclosed in, for example, WO 98/00428, JP H9-506088 T, JP H10-509726 T, JP 2000-44451 A, JP 2000-506873 T, JP 2003-66214 A, JP 2003-313187 A, U.S. Pat. No. 6,468,444, and the like. As the chiral agent, commercially available products can be used such as “S101”, “R811” and “CB15” (trade name, manufactured by Merck, Ltd.); “PALIOCOLOR LC 756” (trade name, manufactured by BASF Ltd.); and “CNL715” and “CNL716” (trade name, manufactured by ADEKA Corporation).

The selective reflection wavelength of the cholesteric liquid crystal polymer layer can be controlled by adjusting the helical pitch. The helical pitch can be controlled by adjusting the amounts of the liquid crystal compound and the chiral agent. For example, when the concentration of the chiral agent is high, the helical twisting force increases, and thus the helical pitch is reduced. As a result, the selective reflection wavelength A of the cholesteric liquid crystal polymer layer shifts to the short wavelength side. If, on the other hand, the concentration of the chiral agent is low, the helical twisting force decreases, and thus the helical pitch is increased. As a result, the selective reflection wavelength A of the cholesteric liquid crystal polymer layer shifts to the long wavelength side. Accordingly, the amount of the chiral agent is preferably 0.1 parts by mass or more and 10 parts by mass or less, and more preferably 0.2 parts by mass or more and 7.0 parts by mass or less with respect to 100 parts by mass of the total of the liquid crystal compound and the chiral agent. If the amount of the chiral agent is 0.1 parts by mass or more and 10 parts by mass or less, the selective reflection wavelength of the resulting cholesteric liquid crystal polymer layer can be controlled so as to be in the near infrared region.

The selective reflection wavelength of the cholesteric liquid crystal polymer layer can be controlled by adjusting the amount of the chiral agent as described above. By controlling the selective reflection wavelength so as to be in the near infrared region, it is possible to obtain a transparent heat-shielding/heat-insulating member that does not substantially absorb light in the visible light region, or in other words, that is transparent in the visible light region and is capable of selectively reflecting light in the near infrared region. The maximum reflectance wavelength of the transparent heat-shielding/heat-insulating member can be set to, for example, 800 nm or more.

Multifunctional Acrylate Compound

As the multifunctional acrylate compound used to form the cholesteric liquid crystal polymer layer, any compound can be used as appropriate as long as it has good compatibility with the liquid crystal compound and the chiral agent and does not disturb the orientation of the cholesteric liquid crystal polymer layer.

The multifunctional acrylate compound is used to improve the curability of the liquid crystal compound having a polymerizable functional group and the chiral agent having a polymerizable functional group, and is added in an amount that does not disturb the orientation of the cholesteric liquid crystal polymer layer. To be specific, the amount of the multifunctional acrylate compound may be 0.5 parts by mass or more and 5 parts by mass or less, and preferably 1 part by mass or more and 3 parts by mass or less with respect to 100 parts by mass of the total of the liquid crystal compound and the chiral agent.

<Pressure-Sensitive Adhesive Layer>

In the transparent heat-shielding/heat-insulating member according to the present invention, it is preferable to dispose a pressure-sensitive adhesive layer on the opposite side of the transparent substrate surface on which the protective layer is formed. With this configuration, the transparent heat-shielding/heat-insulating member according to the present invention can be easily attached to the transparent substrate or the like such as windowpanes. As the material of the pressure-sensitive adhesive layer, a material having high visible light transmittance and a small difference in refractive index to the transparent substrate is preferably used. For example, an acrylic-based resin, a polyester-based resin, a urethane-based resin, a rubber-based resin, a silicone-based resin or the like can be used. Among them, the acrylic-based resin is preferably used since the acrylic-based resin has high optical transparency, excellent balance between wettability and adhesion, and has been produced many results due to high reliability, and it is relatively low in cost. The thickness of the pressure-sensitive adhesive layer is preferably 10 to 100 μm, and more preferably 15 to 50 μm.

In order to suppress the deterioration of the transparent heat-shielding/heat-insulating member caused by ultraviolet rays such as sunlight, the pressure-sensitive adhesive layer preferably contains an ultraviolet absorbing agent. In addition, the pressure-sensitive adhesive layer preferably has a release film thereon until the transparent heat-shielding/heat-insulating member is attached to the transparent substrate for actual use.

<Transparent Heat-Shielding/Heat-Insulating Member>

In the transparent heat-shielding/heat-insulating member according to the present invention, in a reflection spectrum of visible light measured in accordance with JIS R3106-1998; if a “virtual line a” parallel to wavelength axis passes through an average value of a maximum reflectance and a minimum reflectance of the reflection spectrum at a wavelength of 500 to 570 nm, and a point corresponding to a wavelength of 535 nm on the “virtual line a” is a point A; a “virtual line b” parallel to wavelength axis passes through an average value of a maximum reflectance and a minimum reflectance of the reflection spectrum at a wavelength of 620 to 780 nm, and a point corresponding to a wavelength of 700 nm on the “virtual line b” is a point B; and a straight line passing through the point A and the point B that is extended to a wavelength of 500 to 780 nm is a reference line AB, (1) when comparing a reflectance value of the reflection spectrum and a reflectance value of the reference line AB at a wavelength of 500 to 570 nm, if an absolute value of a difference in reflectance value between the reflection spectrum and the reference line AB at a wavelength where the difference in reflectance value between the reflection spectrum and the reference line AB is maximized is defined as a maximum variation difference Δ A, a value of the maximum variation difference Δ A expressed by percentage of reflectance can be set to 7% or less, and (2) when comparing a reflectance value of the reflection spectrum and a reflectance value of the reference line AB at a wavelength of 620 to 780 nm, if an absolute value of a difference in reflectance value between the reflection spectrum and the reference line AB at a wavelength where the difference in reflectance value between the reflection spectrum and the reference line AB is maximized is defined as a maximum variation difference Δ B, a value of the maximum variation difference Δ B expressed by percentage of reflectance can be set to 9% or less.

The difference in reflectance in the above wavelength regions was focused for the following reasons. In the relative luminous efficiency of the human eye, a green region centered on a wavelength of around 500 to 570 nm is strongly perceived. Therefore, when the magnitude of fluctuations called “ripple” (variation in reflectance in vertical direction) caused by a multi-reflective interference of light at a wavelength of 500 to 570 nm is significant in the visible light reflection spectrum of the transparent heat-shielding/heat-insulating member, and even a slight thickness variation of a layer causes phase deviations in the reflection spectrum, which significantly affect the reflection color.

In an infrared reflective film which reflects the near infrared radiation from a thin metal film, inevitably, the reflection spectrum tends to have a shape with a gradual increase in reflectance at the wavelength range in the visible light region to the near infrared region. Accordingly, the reflection color of red tends to be emphasized in the infrared reflective film using the thin metal film. Thus, similarly to the green color region, for the reflection color of red centered on a wavelength of 620 to 780 nm, when the phase deviations caused by the thickness variation of a layer is generated in the reflection spectrum, this can significantly affect the reflection color.

In general, in the transparent heat-shielding/heat-insulating member for use in window lanes or the like, red and yellow that give a feeling of hotness, and green that deteriorates the design quality tend to be avoided. In contrast, blue that gives a feeling of coolness while does not significantly deteriorate the design quality tends to be favored. However, when the thickness of the protective layer is reduced to several hundred nanometers, which overlaps the wavelength range of visible light, there are cases where the reflection colors of red and green in particular become noticeable in the iridescent pattern and in the overall reflection color observed from a different viewing angle, which may deteriorate the appearance. Accordingly, even when the phase deviation caused by a slight thickness variation of a layer is generated, in order to reduce the influence on the reflection color, it is important to suppress the size of ripple in the reflection spectrum in the green light region at a wavelength of 500 to 570 nm and in the red light region at a wavelength of 620 to 780 nm that affect significantly on the reflection color among the wavelengths in the visible light region.

Next, the maximum variation difference Δ A and the maximum variation difference Δ B will be described with reference to drawings. FIG. 4 is a diagram showing a reflection spectrum of the transparent heat-shielding/heat-insulating member of Example 1 of the present invention described later. In FIG. 4, a surface of a transparent heat-shielding/heat-insulating member on which the protective layer is not formed is attached to a glass plate using an ultraviolet shielding transparent adhesive, and in accordance with JIS R3106-1998, the reflection spectrum is measured from the glass plate side.

First, in the measured reflection spectrum, a maximum reflectance and a minimum reflectance at a wavelength of 500 to 570 are obtained. Next, a “virtual line a” that represents an average value of the obtained maximum reflectance and minimum reflectance is obtained, and a point at a wavelength of 535 nm on the “virtual line a” is set as a point A. In a similar manner, a “virtual line b” that represents an average value of a maximum reflectance and minimum reflectance at a wavelength of 620 to 780 nm is obtained, and a point at a wavelength of 700 nm on the “virtual line b” is set as a point B. A straight line passing through the points A and B is extended to a wavelength of 500 to 780 nm to make a reference line AB Next, (1) when comparing a reflectance value of the reflection spectrum and a reflectance value of the reference line AB at a wavelength of 500 to 570 nm, an absolute value of a difference in reflectance value between the reflection spectrum and the reference line AB at a wavelength where the difference in reflectance value between the reflection spectrum and the reference line AB is maximized is defined as a maximum variation difference Δ A. Similarly, (2) when comparing a reflectance value of the reflection spectrum and a reflectance value of the reference line AB at a wavelength of 620 to 780 nm, an absolute value of a difference in reflectance value between the reflection spectrum and the reference line AB at a wavelength where the difference in reflectance value between the reflection spectrum and the reference line AB is maximized is defined as a maximum variation difference Δ B. When doing so, if the values of the maximum variation differences Δ A and Δ B are small, this means that the size of ripple in the reflection spectrum is suppressed, and the variation in reflectance in the reflection spectrum at a wavelength of 500 to 780 nm corresponding to the green to red region can be reduced, and for example, even if a thickness variation is generated in the same film, the influence on the reflection color can be suppressed to a level where it is hardly recognized with the human eyes.

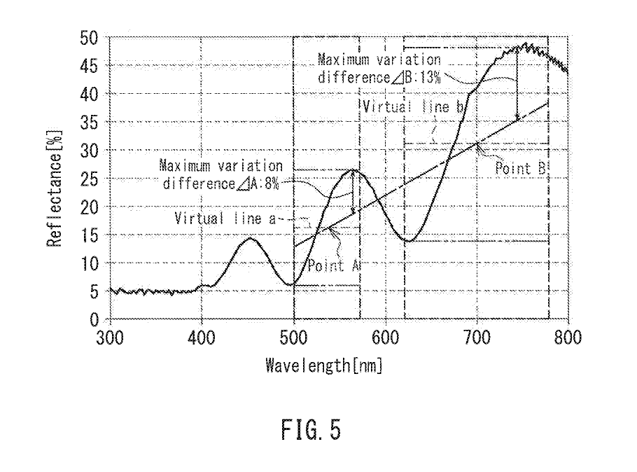

FIG. 5 is a diagram showing a reflection spectrum of a transparent heat-shielding/heat-insulating member of Comparative Example 1 of the present invention described later. In FIG. 5, maximum variation differences Δ A and Δ B were obtained in the same manner as described above.

In the transparent heat-shielding/heat-insulating member according to the present invention, it is preferable to set the value of the maximum variation difference Δ A expressed by percentage of reflectance to 7% or less, and set the value of the maximum variation difference Δ B expressed by percentage of reflectance to 9% or less. By setting the values of the maximum variation differences Δ A and Δ B within the above-ranges, the variation difference in reflectance in the reflection spectrum, which moves in conjunction with a wavelength in a range of 500 to 780 nm corresponding to the green to red region in particular, can be significantly reduced and the variation in reflectance can be moderated. Thus, even when the protective layer is set to have a total thickness in a range that overlaps the wavelength range of visible light (380 to 780 nm) for the sake of both scratch resistance and heat insulation properties, a reflection color change caused by the iridescent phenomenon and the viewing angle can be suppressed to a level where the reflection color change is hardly recognized with the human eyes, and an excellent appearance can be accomplished. When the value of the maximum variation difference Δ A is more than 7%, and the value of the maximum variation difference Δ B is more than 9%, the variation difference in reflectance in the visible light reflection spectrum at a wavelength of 500 to 780 nm corresponding to the green to red region cannot be reduced sufficiently, and as a result of which, when the protective layer is set to have a total thickness in a range that overlaps the wavelength range of visible light (380 to 780 nm) for the sake of both scratch resistance and heat insulation properties, it is difficult to suppress the iridescent phenomenon and a reflection color change caused by the viewing angle sufficiently.

In the transparent heat-shielding/heat-insulating member according to the present invention, the normal emissivity measured based on JIS R3106-1998 can be set to 0.22 or less (a heat transmission coefficient value of 4.2 W/m²·K or less) on the functional layer side.

With the transparent heat-shielding/heat-insulating member according to the present invention, even after it is subjected to a 1000-hour weather resistance test according to JIS A5759, separation of the protective layer is not observed in a cross cut adhesion test according to JIS D0202-1998.

The transparent heat-shielding/heat-insulating member according to the present invention can be set to have, when the pressure-sensitive adhesive layer disposed on the transparent substrate is attached to a glass substrate, an average light reflectance at a wavelength of 5.5 to 25.2 μm of 80% or more, the average light reflectance being measured by applying light from the opposite side of the glass substrate.

Also, with the transparent heat-shielding/heat-insulating member according to the present invention, the heat-insulating function and the heat-shielding function can be provided by the infrared reflective layer, and the scratch resistance can be improved and the heat-insulating function can be maintained by the protective layer. Furthermore, the transparent heat-shielding/heat-insulating member according to the present invention can further improve the heat-shielding function by further disposing the cholesteric liquid crystal polymer layer.

The transparent heat-shielding/heat-insulating member according to the present invention is in the form of a film or sheet, and can be used by being attached to a glass substrate or the like using a pressure-sensitive adhesive, an adhesive, etc., but may be used in any other form.

Next, an example of a method for producing a transparent heat-shielding/heat-insulating member according to the present invention will be described with reference to FIG. 1.

First, an infrared reflective layer 21 is formed on one of the surfaces of the transparent substrate 11. The infrared reflective layer 21 can be formed by, for example, a dry coating method such as a method of sputtering a conductive material, transparent dielectric material or the like, but may be formed by any other method. The infrared reflective layer 21 is preferably configured to have a three-layer structure including a metal suboxide layer 12 as a high refractive index dielectric layer, a metal layer 13 as a low refractive index dielectric layer and a metal suboxide layer 14 as a high refractive index dielectric layer, from the viewpoint of the heat-shielding/heat-insulating function, corrosion resistance and productivity. In particular, the metal suboxide layer 12 and the metal suboxide layer 14 are preferably formed by a reactive sputtering method. It is thereby possible to reliably form the metal suboxide layer in which a metal is partially oxidized.

Next, an optical adjustment layer 15 is formed on the infrared reflective layer 21. Subsequently, a medium refractive index layer 16 is formed on the optical adjustment layer 15, and a high refractive index layer 17 is formed on the medium refractive layer 16. Furthermore, a low refractive index layer 18 is formed on the high refractive index layer 17. Each of these layers can be formed by a wet coating method. It is thereby possible to, even when the infrared reflective layer 21 is provided on the indoor side, prevent the infrared reflective layer 21 from damage caused by cleaning the window or the like. Also, in terms of the appearance, it is possible to suppress the iridescent phenomenon and angle dependence such as a change in reflection color caused by the viewing angle, and further the heat-insulating function of the infrared reflective layer can be maintained.

Finally, a pressure-sensitive adhesive layer 19 is formed on the other surface of the transparent substrate 11. There is no particular limitation on the method for forming the pressure-sensitive adhesive layer 19, and the pressure-sensitive adhesive layer 19 may be formed by applying a pressure-sensitive adhesive directly onto the outer surface of the transparent substrate 11, or by attaching a separately prepared pressure-sensitive adhesive sheet to the outer surface of the transparent substrate 11.

Through the process described above, an example of a transparent heat-shielding/heat-insulating member according to the present invention is obtained, and is used by being attached to a glass substrate or the like as needed.

Hereinafter, the present invention will be described in detail by way of examples. It is to be noted, however, that the present invention is not limited to the examples given below. Also, unless otherwise stated, the term “part(s)” means “part(s) by mass”.

Measurement of Refractive Index

The refractive index of the optical adjustment layer, the medium refractive index layer, the high refractive index layer and the low refractive index layer obtained in each of the following examples and comparative examples were measured by the following method.

A film sample for refractive index measurement was produced by applying a coating material for forming each layer onto a surface, not being subjected to an adhesion promotion treatment, of a polyethylene terephthalate (PET) film “A4100” (trade name, manufactured by Toyobo Co., Ltd., thickness: 50 μm) having an adhesion promoted surface, so as to have a thickness of 500 nm, and then drying the coating material. In the case of using an ultraviolet curable coating material in the coating material for forming each layer, the film sample for refractive index measurement was produced by further, after drying, applying ultraviolet rays in an amount of 300 mJ/cm² with a high-pressure mercury lamp so as to cure the coating material.

A black tape was attached to the back side of the produced sample for refractive index measurement, a reflection spectrum was obtained by using a reflectance spectroscopic thickness meter “FE-3000” (manufactured by Otsuka Electronics Co., Ltd.), and fitting was performed from n-Cauchy equation based on the obtained reflection spectrum, and the light refractive index at a wavelength of 550 nm of each layer was obtained.

Measurement of Thickness

The thickness of the optical adjustment layer, the medium refractive index layer, the high refractive index layer and the low refractive index layer obtained in each of the following examples and comparative examples were measured by attaching a black tape on a surface of the transparent substrate on which the infrared reflective layer and the protective layer were not formed, obtaining a reflection spectrum for each layer by an instantaneous multi-purpose photometric system “MCPD-3000” (manufactured by Otsuka Electronics Co., Ltd.), and performing optimization fitting by using a refractive index obtained by the above refractive index measurement from the obtained reflection spectrum.

### Example 1

### Production of Infrared Reflective Layer-Bearing Transparent Substrate

First, using the aforementioned PET film “A4100” as a transparent substrate, a 2 nm thick metal suboxide (TiOₓ) layer was formed on the adhesion promoted surface of the PET film by a reactive sputtering method using a titanium target. As a sputtering gas of the reactive sputtering method, a mixed gas of Ar and O₂ (gas volume flow ratio: Ar 97%: O₂ 3%) was used. Next, a 10 nm thick metal (Ag) layer was formed on the metal suboxide layer by a sputtering method using a silver target. As a sputtering gas of the sputtering method, an Ar gas (Ar: 100%) was used. Furthermore, a 2 nm thick metal suboxide (TiOₓ) layer was formed on the metal layer by a reactive sputtering method using a titanium target. As a sputtering gas of the reactive sputtering method, a mixed gas of Ar and O₂ (gas volume flow ratio: Ar 97%: O₂ 3%) was used. By doing so, an infrared reflective layer-bearing transparent substrate having a three-layer structure composed of, from the transparent substrate side, a metal suboxide (TiOₓ) layer, a metal (Ag) layer, a metal suboxide (TiOₓ) layer was prepared. The x of the TiOₓ layer was 1.5.

<Optical Adjustment Layer>

An optical adjustment coating material A was produced by mixing, in a Disper, 10 parts of titanium oxide-based hard coating agent “Liodulas TYT80-01” (trade name, manufactured by Toyo Ink Mfg Co., Ltd., solid content: 25 mass %, refractive index: 1.80 [nominal value]) and 90 parts of methyl isobutyl ketone as a dilution solvent. Next, the optical adjustment coating material A was applied onto the infrared reflective layer by using an micro-gravure coater (manufactured by Yasui Seiki Co., Ltd.) and dried so as to have a dry thickness of 40 nm, and thereafter irradiated with ultraviolet rays in an amount of 300 mJ/cm² with a high-pressure mercury lamp so as to cure the coating material. A 40 nm thick optical adjustment layer was thereby formed. The refractive index of the produced optical adjustment layer was measured by the above-described method and found to be 1.80.

<Medium Refractive Index Layer>

A medium refractive index coating material A was produced by mixing, in a Disper, 10 parts of hard coating agent “Z-773” (trade name, manufactured by Aica Kogyo Co., Ltd., solid content: 34 mass %, refractive index: 1.53 [nominal value]), and 100 parts of butyl acetate as a dilution solvent. Next, the medium refractive index coating material A was applied onto the optical adjustment layer by using aforementioned micro-gravure coater and dried so as to have a dry thickness of 80 nm, and thereafter irradiated with ultraviolet rays in an amount of 300 mJ/cm² with a high-pressure mercury lamp so as to cure the coating material. A80 nm thick medium refractive index layer was thereby formed. The refractive index of the produced medium refractive index layer was measured by the above-described method and found to be 1.52.

<High Refractive Index Layer>

A high refractive index coating material A was produced by mixing, in a Disper, 40 parts of titanium oxide-based hard coating agent “Liodulas TYT 80-01” (trade name, manufactured by Toyo Ink Mfg Co., Ltd., solid content: 25 mass %, refractive index: 1.80 [nominal value]) and 60 parts of methyl isobutyl ketone as a dilution solvent. Next, the high refractive index coating material A was applied onto the medium refractive index layer by using aforementioned micro-gravure coater and dried so as to have a dry thickness of 270 nm, and thereafter irradiated with ultraviolet rays in an amount of 300 mJ/cm² with a high-pressure mercury lamp so as to cure the coating material. A270 nm thick high refractive index layer was thereby formed. The refractive index of the produced high refractive index layer was measured by the above-described method and found to be 1.80.

<Low Refractive Index Layer>

A hollow silica-containing low refractive index coating material “ELCOM P-5062” (trade name, manufactured by JGC Catalysts and Chemicals Ltd., solid content: 3 mass %, refractive index: 1.38 [nominal value]) was used as a low refractive index coating material A, and the low refractive index coating material A was applied onto the high refractive index layer by using the aforementioned micro-gravure coater and dried so as to have a dry thickness of 100 nm, and thereafter irradiated with ultraviolet rays in an amount of 300 mJ/cm² with a high-pressure mercury lamp so as to cure the coating material. A 100 nm thick low refractive index layer was thereby formed. The refractive index of the produced low refractive index layer was measured by the above-described method and found to be 1.38.

In the manner described above, an infrared reflective film (transparent heat-shielding/heat-insulating member) having a protective layer composed of the optical adjustment layer, the medium refractive index layer, the high refractive index layer and the low refractive index layer was produced.

<Formation of Pressure-Sensitive Adhesive Layer>

First, a PET film “NS-38+A” (trade name, manufactured by Nakamoto Packs Co., Ltd., thickness: 38 μm) having a silicone-treated surface was prepared. A pressure-sensitive adhesive coating material was prepared by adding 1.25 parts of ultraviolet absorbing agent (benzophenone) manufactured by Wako Pure Chemical Industries, Ltd., and 0.27 parts of cross-linking agent “E-AX” (trade name, manufactured by Soken Chemical & Engineering Co., Ltd., solid content: 5%) to 100 parts of acrylic-based pressure-sensitive adhesive “SK Dyne 2094” (trade name, manufactured by Soken Chemical & Engineering Co., Ltd., solid content: 25 mass %) and mixing them in a Disper.

Next, the pressure-sensitive adhesive coating material was applied onto the silicone-treated surface of the PET film and dried so as to have a dry thickness of 25 μm, and a pressure-sensitive adhesive layer was thereby formed. Furthermore, the surface of the infrared reflective film on which the infrared reflective layer was not formed was attached to the upper surface of the pressure-sensitive adhesive layer, and a pressure-sensitive adhesive layer-bearing infrared reflective film was thereby produced.

<Attachment to Glass Substrate>

First, a 3 mm-thick float glass sheet (manufactured by Nippon Sheet Glass Co. Ltd.) was prepared as a glass substrate. Next, the PET film was removed from the pressure-sensitive adhesive layer-bearing infrared reflective film, and the pressure-sensitive adhesive layer-side surface of the pressure-sensitive adhesive layer-bearing infrared reflective film was attached to the float glass sheet.

### Example 2

A pressure-sensitive adhesive layer-bearing infrared reflective film was produced in the same manner as in Example 1 except that the thickness of the optical adjustment layer was changed to 60 nm, the thickness of the medium refractive index layer was changed to 60 nm, the thickness of the high refractive index layer was changed to 80 nm and the thickness of the low refractive index layer was changed to 110 nm, and the pressure-sensitive adhesive layer-bearing infrared reflective film was then attached to a glass substrate.

### Example 3

A pressure-sensitive adhesive layer-bearing infrared reflective film was produced in the same manner as in Example 1 except that the thickness of the optical adjustment layer was changed to 60 nm, the thickness of the medium refractive index layer was changed to 100 nm, the thickness of the high refractive index layer was changed to 400 nm and the thickness of the low refractive index layer was changed to 110 nm, and the pressure-sensitive adhesive layer-bearing infrared reflective film was then attached to a glass substrate.

### Example 4

A pressure-sensitive adhesive layer-bearing infrared reflective film was produced in the same manner as in Example 1 except that the optical adjustment layer and the medium refractive index layer were not formed and the thickness of the high refractive index layer was changed to 240 nm and the thickness of the low refractive index layer was changed to 110 nm, and the pressure-sensitive adhesive layer-bearing infrared reflective film was then attached to a glass substrate.

### Example 5

A pressure-sensitive adhesive-bearing infrared reflective film was produced in the same manner as in Example 1 except that a cholesteric liquid crystal polymer layer was formed in the following manner on the opposite side of a transparent substrate surface on which the protective layer (the non-adhesion promoted surface of the PET film) was formed after the infrared reflective layer of Example 1 was formed, and the produced pressure-sensitive adhesive-bearing infrared reflective film was then attached to a glass substrate.

<Formation of Cholesteric Liquid Crystal Polymer Layer>

A cholesteric liquid crystal polymer coating material was prepared by mixing and stirring the following materials:

(1) 86.4 parts of liquid crystal compound I having a polymerizable functional group (high melting point liquid crystal compound, trade name “PLC-7700” manufactured by ADEKA Corporation, melting point: 90° C.);

(2) 9.6 parts of liquid crystal compound II having a polymerizable functional group (low melting point liquid crystal compound, trade name “PLC-8100” manufactured by ADEKA Corporation, melting point: 65° C.);

(3) 4.0 parts of chiral agent (right-handed chiral agent, trade name “CNL-715” manufactured by ADEKA Corporation);

(4) 1.5 parts of multifunctional acrylate compound (trade name “Light Acrylate PE-3A” manufactured by Kyoeisha Chemical Co., Ltd.);

(5) 3.0 parts of photopolymerization initiator (trade name “Irgacure 819” manufactured by BASF Ltd.); and

(6) 464 parts of solvent (cyclohexanone).

A coating film was formed by applying the cholesteric liquid crystal polymer coating material onto a surface of the infrared reflective film produced in Example 1 on which the infrared reflective layer was not formed by using a micro-gravure coater, and then dried at 100° C. The coating film was irradiated with ultraviolet rays in an amount of 300 mJ/cm² with a high-pressure mercury lamp so as to cure the coating material, and a right-handed cholesteric liquid crystal polymer layer (thickness: 3 μm) was formed. The right-handed cholesteric liquid crystal polymer layer had a center reflection wavelength of 890 nm.

### Example 6

Using the aforementioned PET film “A4100” as a transparent substrate, a 2 nm thick metal oxide (TiO₂) layer was formed on the adhesion promoted surface of the PET film by a sputtering method using a titanium oxide target. As a sputtering gas of the sputtering method, an Ar gas (Ar: 100%) was used. Next, a 10 nm thick metal (Ag) layer was formed on the metal oxide layer by a sputtering method using a silver target. As a sputtering gas of the sputtering method, an Ar gas (Ar: 100%) was used. Furthermore, a 2 nm thick metal suboxide (TiOₓ) layer was formed on the metal layer by a reactive sputtering method using a titanium target. As a sputtering gas of the reactive sputtering method, a mixed gas of Ar and O₂ (gas volume flow ratio: Ar 97%: O₂ 3%) was used. By doing so, an infrared reflective layer-bearing transparent substrate having a three-layer structure composed of, from the transparent substrate side, a metal oxide (TiO₂) layer, a metal (Ag) layer, a metal suboxide (TiOₓ) layer in this order was prepared. The x of the TiOₓ layer was 1.5.

Next, a pressure-sensitive adhesive layer-bearing infrared reflective film was produced in the same manner as in Example 1 except that the infrared reflective layer-bearing transparent substrate was used, and the pressure-sensitive adhesive layer-bearing infrared reflective film was then attached to a glass substrate.

### Example 7

A medium refractive index coating material B was produced by mixing, in a Disper, 9.5 parts of pentaerythritol triacrylate “PE-3A” (trade name, manufactured by Kyoeisha Chemical Co., Ltd.), 0.5 parts of phosphoric acid group-containing methacrylate “KAYAMER PM-21” (trade name, manufactured by Nippon Kayaku Co., Ltd.), 0.3 parts of photopolymerization initiator “Irgacure 184” (trade name, manufactured by BASF Ltd.), and 490 parts of methyl isobutyl ketone.

Next, a 130 nm-thick medium refractive index layer was formed by applying the medium refractive index coating material B onto an infrared reflective layer-bearing transparent substrate produced in the same manner as in Example 1 by using the aforementioned micro-gravure coater and dried so as to have a dry thickness of 130 nm, and thereafter irradiated with ultraviolet rays in an amount of 300 mJ/cm² with a high-pressure mercury lamp so as to cure the coating material. A 130 nm thick medium refractive index layer was thereby formed. As described above, a pressure-sensitive adhesive layer-bearing infrared reflective film was produced in the same manner as in Example 1 except that the medium refractive index layer was formed without providing the optical adjustment layer, and the pressure-sensitive adhesive layer-bearing infrared reflective film was then attached to a glass substrate. The refractive index of the produced medium refractive index coating material B was measured by the above-described method and found to be 1.50.

### Example 8

A pressure-sensitive adhesive layer-bearing infrared reflective film was produced in the same manner as in Example 1 except that the thickness of the optical adjustment layer was changed to 50 nm, the thickness of the medium refractive index layer was changed to 130 nm and the thickness of the high refractive index layer was changed to 500 nm, and the pressure-sensitive adhesive layer-bearing infrared reflective film was then attached to a glass substrate.

### Example 9

A pressure-sensitive adhesive layer-bearing infrared reflective film was produced in the same manner as in Example 1 except that the thickness of the metal (Ag) layer of the infrared reflective layer was changed to 8 nm, the thickness of the optical adjustment layer was changed to 50 nm, the thickness of the medium refractive index layer was changed to 55 nm, the thickness of the high refractive index layer was changed to 65 nm and the thickness of the low refractive index layer was changed to 95 nm, and the pressure-sensitive adhesive layer-bearing infrared reflective film was then attached to a glass substrate.

### Example 10

A pressure-sensitive adhesive layer-bearing infrared reflective film was produced in the same manner as in Example 1 except that the optical adjustment layer and the medium refractive index layer were not formed and the thickness of the high refractive index layer was changed to 100 nm and the thickness of the low refractive index layer was changed to 110 nm, and the pressure-sensitive adhesive layer-bearing infrared reflective film was then attached to a glass substrate.

### Example 11

A pressure-sensitive adhesive layer-bearing infrared reflective film was produced in the same manner as in Example 1 except that the optical adjustment layer and the high refractive index layer were changed to the following and the thickness of the medium refractive index layer was changed to 50 nm, and the pressure-sensitive adhesive layer-bearing infrared reflective film was then attached to a glass substrate.

<Optical Adjustment Layer>

An optical adjustment coating material B was produced by mixing, in a Disper, 10 parts of titanium oxide-based hard coating agent “Liodulas TYT 90” (trade name, manufactured by Toyo Ink Mfg Co., Ltd., solid content: 25 mass %, refractive index: 1.90 [nominal value]) and 90 parts of methyl isobutyl ketone as a dilution solvent. Next, the optical adjustment coating material B was applied onto the infrared reflective layer by using an micro-gravure coater (manufactured by Yasui Seiki Co., Ltd.) and dried so as to have a dry thickness of 76 nm, and thereafter irradiated with ultraviolet rays in an amount of 500 mJ/cm² with a high-pressure mercury lamp so as to cure the coating material. A 76 nm thick optical adjustment layer was thereby formed. The refractive index of the produced optical adjustment layer was measured by the above-described method and found to be 1.89.

<High Refractive Index Layer>

A high refractive index coating material B was produced by mixing, in a Disper, 40 parts of titanium oxide-based hard coating agent “Liodulas TYT 90” (trade name, manufactured by Toyo Ink Mfg Co., Ltd., solid content: 25 mass %, refractive index: 1.90 [nominal value]) and 60 parts of methyl isobutyl ketone as a dilution solvent. Next, the high refractive index coating material B was applied onto the medium refractive index layer by using aforementioned micro-gravure coater and dried so as to have a dry thickness of 220 nm, and thereafter irradiated with ultraviolet rays in an amount of 500 mJ/cm² with a high-pressure mercury lamp so as to cure the coating material. A 220 nm thick high refractive index layer was thereby formed. The refractive index of the produced high refractive index layer was measured by the above-described method and found to be 1.89.

### Example 12

A pressure-sensitive adhesive layer-bearing infrared reflective film was produced in the same manner as in Example 2 except that the high refractive index layer was changed to the following, and the pressure-sensitive adhesive layer-bearing infrared reflective film was then attached to a glass substrate.

<High Refractive Index Layer>

A high refractive index coating material C was produced by mixing, in a Disper, 25 parts of zirconium oxide-based hard coating agent “Liodulas TYZ 74” (trade name, manufactured by Toyo Ink Mfg Co., Ltd., solid content: 40 mass %, refractive index: 1.74 [nominal value]) and 75 parts of methyl isobutyl ketone as a dilution solvent. Next, the high refractive index coating material C was applied onto the medium refractive index layer by using a micro-gravure coater (manufactured by Yasui Seiki Co., Ltd.) and dried so as to have a dry thickness of 80 nm, and thereafter irradiated with ultraviolet rays in an amount of 300 mJ/cm² with a high-pressure mercury lamp so as to cure the coating material. A80 nm thick high refractive index layer was thereby formed. The refractive index of the produced high refractive index layer was measured by the above-described method and found to be 1.76.

### Example 13

A pressure-sensitive adhesive layer-bearing infrared reflective film was produced in the same manner as in Example 2 except that the optical adjustment layer and the high refractive index layer were changed to the following and the thickness of the low refractive index layer was changed to 115 nm, and the pressure-sensitive adhesive layer-bearing infrared reflective film was then attached to a glass substrate.

<Optical Adjustment Layer>

An optical adjustment coating material B was produced by mixing, in a Disper, 10 parts of titanium oxide-based hard coating agent “Liodulas TYT 90” (trade name, manufactured by Toyo Ink Mfg Co., Ltd., solid content: 25 mass %, refractive index: 1.90 [nominal value]) and 90 parts of methyl isobutyl ketone as a dilution solvent. Next, the optical adjustment coating material B was applied onto the infrared reflective layer by using an micro-gravure coater (manufactured by Yasui Seiki Co., Ltd.) and dried so as to have a dry thickness of 55 nm, and thereafter irradiated with ultraviolet rays in an amount of 500 mJ/cm² with a high-pressure mercury lamp so as to cure the coating material. A 55 nm thick optical adjustment layer was thereby formed. The refractive index of the produced optical adjustment layer was measured by the above-described method and found to be 1.89.

<High Refractive Index Layer>

A high refractive index coating material D was produced by mixing, in a Disper, 25 parts of zinc oxide-based hard coating agent “Liodulas TYN 700UV” (trade name, manufactured by Toyo Ink Mfg Co., Ltd., solid content: 40 mass %, refractive index: 1.64 [nominal value]) and 75 parts of methyl isobutyl ketone as a dilution solvent. Next, the high refractive index coating material D was applied onto the medium refractive index layer by using aforementioned micro-gravure coater and dried so as to have a dry thickness of 85 nm, and thereafter irradiated with ultraviolet rays in an amount of 500 mJ/cm² with a high-pressure mercury lamp so as to cure the coating material. A85 nm thick high refractive index layer was thereby formed. The refractive index of the produced high refractive index layer was measured by the above-described method and found to be 1.65.

### Example 14

A pressure-sensitive adhesive layer-bearing infrared reflective film was produced in the same manner as in Example 1 except that the optical adjustment layer was changed to the following and the thickness of the metal (Ag) layer of the infrared reflective layer was changed to 8 nm, the thickness of the medium refractive index layer was changed to 100 nm, the thickness of the high refractive index layer was changed to 320 nm and the thickness of the low refractive index layer was changed to 110 nm, and the pressure-sensitive adhesive layer-bearing infrared reflective film was then attached to a glass substrate.

<Optical Adjustment Layer>

An optical adjustment coating material C was produced by mixing, in a Disper, 10 parts of titanium oxide-based hard coating agent “Liodulas TYT 80-1” (trade name, manufactured by Toyo Ink Mfg Co., Ltd., solid content: 25 mass %, refractive index: 1.80 [nominal value]), 2.2 parts of urethane acrylate-based ionizing radiation curable resin solution “BPZA-66” (trade name, manufactured by Kyoeisha Chemical Co., Ltd., solid content: 80 mass %, weight-average molecular weight: 20,000), 0.1 parts of phosphoric acid group-containing methacrylate “KAYAMER PM-21” (trade name, manufactured by Nippon Kayaku Co., Ltd.), and 162 parts of methyl isobutyl ketone as a dilution solvent. Next, the optical adjustment coating material C was applied onto the infrared reflective layer by using an micro-gravure coater (manufactured by Yasui Seiki Co., Ltd.) and dried so as to have a dry thickness of 55 nm, and thereafter irradiated with ultraviolet rays in an amount of 300 mJ/cm² with a high-pressure mercury lamp so as to cure the coating material. A 55 nm thick optical adjustment layer was thereby formed. The refractive index of the produced optical adjustment layer was measured by the above-described method and found to be 1.60.

### Example 15

A pressure-sensitive adhesive layer-bearing infrared reflective film was produced in the same manner as in Example 2 except that the low refractive index layer was changed to the following, and the pressure-sensitive adhesive layer-bearing infrared reflective film was then attached to a glass substrate.

<Low Refractive Index Layer>

A low refractive index coating material B was produced by mixing, in a Disper, 100 parts of hollow silica-containing low refractive index coating material “ELCOM P-5062” (trade name, manufactured by JGC Catalysts and Chemicals Ltd., solid content: 3 mass %, refractive index: 1.38 [nominal value]), 3.5 parts of pentaerythritol triacrylate “Light Acrylate PE-3A” (trade name, manufactured by Kyoeisha Chemical Co., Ltd.), 1.8 parts of dipentaerythritol hexa acrylate “KAYALAD DPHA” (trade name, manufactured by Nippon Kayaku Co., Ltd.), 117 parts of isopropyl alcohol, 26 parts of methyl isobutyl ketone, and 26 parts of isopropyl glycol. The low refractive index coating material B was applied onto the high refractive index layer by using an aforementioned micro-gravure coater and dried so as to have a dry thickness of 100 nm, and thereafter irradiated with ultraviolet rays in an amount of 300 mJ/cm² with a high-pressure mercury lamp so as to cure the coating material. A 100 nm thick low refractive index layer was thereby formed. The refractive index of the produced low refractive index layer was measured by the above-described method and found to be 1.45.

### Example 16

A pressure-sensitive adhesive layer-bearing infrared reflective film was produced in the same manner as in Example 1 except that the thickness of the metal (Ag) layer of the infrared reflective layer was changed to 8 nm, the thickness of the optical adjustment layer was changed to 60 nm, the thickness of the medium refractive index layer was changed to 200 nm, the thickness of the high refractive index layer was changed to 550 nm and the thickness of the low refractive index layer was changed to 120 nm, and the pressure-sensitive adhesive layer-bearing infrared reflective film was then attached to a glass substrate.

### Example 17

A pressure-sensitive adhesive layer-bearing infrared reflective film was produced in the same manner as in Example 1 except that the thickness of the metal suboxide (TiOₓ) layer of the infrared reflective layer was changed to 6 nm, the thickness of the metal (Ag) layer was changed to 8 nm, the thickness of the optical adjustment layer was changed to 80 nm, the thickness of the medium refractive index layer was changed to 100 nm, the thickness of the high refractive index layer was changed to 505 nm and the thickness of the low refractive index layer was changed to 115 nm, and the pressure-sensitive adhesive layer-bearing infrared reflective film was then attached to a glass substrate.

### Example 18

A pressure-sensitive adhesive layer-bearing infrared reflective film was produced in the same manner as in Example 1 except that the thickness of the metal (Ag) layer of the infrared reflective layer was changed to 12 nm, the thickness of the optical adjustment layer was changed to 45 nm, the thickness of the medium refractive index layer was changed to 90 nm, the thickness of the high refractive index layer was changed to 95 nm and the thickness of the low refractive index layer was changed to 100 nm, and the pressure-sensitive adhesive layer-bearing infrared reflective film was then attached to a glass substrate.

### Comparative Example 1

Using the aforementioned PET film “A4100” as a transparent substrate, a 30 nm thick metal oxide (ITO) layer was formed on the adhesion promoted surface of the PET film by a sputtering method using an indium tin oxide (ITO) target. As a sputtering gas of the sputtering method, an Ar gas (Ar: 100%) was used. Next, a 12 nm thick metal (Ag) layer was formed on the metal oxide layer by a sputtering method using a silver target. As a sputtering gas of the sputtering method, an Ar gas (Ar: 100%) was used. Furthermore, a 30 nm thick metal oxide (ITO) layer was formed on the metal oxide layer by a sputtering method using an indium tin oxide (ITO) target. As a sputtering gas of the sputtering method, an Ar gas (Ar: 100%) was used. By doing so, an infrared reflective layer-bearing transparent substrate having a three-layer structure composed of, from the transparent substrate side, a metal oxide (ITO) layer, a metal (Ag) layer, a metal oxide (ITO) layer in this order was prepared.

A medium refractive index coating material C was produced by mixing, in a Disper, 125 parts of urethane acrylate-based ionizing radiation curable resin solution “BPZA-66” (trade name, manufactured by Kyoeisha Chemical Co., Ltd., solid content: 80 mass %, weight-average molecular weight: 20,000), 5 parts of phosphoric acid group-containing methacrylate “KAYAMER PM-21” (trade name, manufactured by Nippon Kayaku Co., Ltd.), and 3 parts of photopolymerization initiator “Irgacure 819” (trade name, manufactured by BASF Ltd.), and 375 parts of methyl isobutyl ketone.

Next, the medium refractive index coating material C was applied onto the infrared reflective layer of the infrared reflective layer-bearing transparent substrate by using an aforementioned micro-gravure coater and dried so as to have a dry thickness of 800 nm, and thereafter irradiated with ultraviolet rays in an amount of 300 mJ/cm² with a high-pressure mercury lamp so as to cure the coating material. A 800 nm thick medium refractive index layer was thereby formed. As described above, the pressure-sensitive adhesive layer-bearing infrared reflective film was prepared in the same manner as in Example 1 except that only the medium refractive index layer was formed and then attached to a glass substrate. The refractive index of the produced medium refractive index layer was measured by the above-described method and found to be 1.50.

### Comparative Example 2

An infrared reflective layer-bearing transparent substrate having a three-layer structure composed of, from the transparent substrate side, a metal suboxide (TiOₓ) layer, a metal (Ag) layer, a metal suboxide (TiOₓ) layer was prepared in the same manner as in Example 1.

Next, the optical adjustment coating material A was applied onto the infrared reflective layer in the same manner as in Example 1 and dried so as to have a dry thickness of 40 nm, and thereafter irradiated with ultraviolet rays in an amount of 300 mJ/cm² with a high-pressure mercury lamp so as to cure the coating material. A40 nm thick optical adjustment layer was thereby formed. Next, the medium refractive index coating material C prepared in Comparative Example 1 was applied onto the optical adjustment layer and dried so as to have a dry thickness of 3000 nm, and thereafter irradiated with ultraviolet rays in an amount of 300 mJ/cm² with a high-pressure mercury lamp so as to cure the coating material. A 3000 nm thick medium refractive index layer was thereby formed. As described above, a pressure-sensitive adhesive layer-bearing infrared reflective film was produced in the same manner as in Example 1 except that only the optical adjustment layer and the medium refractive index layer were formed, and the pressure-sensitive adhesive layer-bearing infrared reflective film was then attached to a glass substrate.

### Comparative Example 3

A pressure-sensitive adhesive layer-bearing infrared reflective film was produced in the same manner as in Example 1 except that the thickness of the optical adjustment layer was changed to 50 nm, the thickness of the medium refractive index layer was changed to 150 nm, the thickness of the high refractive index layer was changed to 700 nm and the thickness of the low refractive index layer was changed to 110 nm, and the pressure-sensitive adhesive layer-bearing infrared reflective film was then attached to a glass substrate.

### Comparative Example 4

A pressure-sensitive adhesive layer-bearing infrared reflective film was produced in the same manner as in Example 1 except that the optical adjustment layer, the medium refractive index layer and the high refractive index layer were not formed and the thickness of the low refractive index layer was changed to 80 nm, and the pressure-sensitive adhesive layer-bearing infrared reflective film was then attached to a glass substrate.

<Evaluation of Transparent Heat-Shielding/Heat-Insulating Member>

The infrared reflective films of Examples 1 to 18 and Comparative Examples 1 to 4 described above, each being attached to a glass substrate, were subjected to the following measurements so as to obtain maximum variation difference in reflectance, visible light transmittance, haze, normal emissivity, shading coefficient and heat transmission coefficient. In addition, the infrared reflective films were evaluated in terms of the initial adhesion of the protective layer, adhesion after a weather resistance test, scratch resistance, corrosion resistance, and furthermore, iridescent property and angle dependence were observed as the appearance of the infrared reflective film.

Maximum Variation Difference in Reflectance

Spectral transmittance was measured in a range of 300 to 800 nm based on JIS R3106-1998 by using a UV-Vis-NIR spectrophotometer Ubest V-570 type (trade name, manufactured by JASCO Corporation), with the glass substrate side being set as the light-entering side. Reflection spectrum of Example 1 is shown in FIG. 4, and reflection spectrum of Comparative Example 1 is shown in FIG. 5.

Next, as shown in FIGS. 4 and 5, in the measured reflection spectrum; in a reflection spectrum measured according to JIS R3106-1998; if a “virtual line a” parallel to wavelength axis passes through an average value of a maximum reflectance and a minimum reflectance of the reflection spectrum at a wavelength of 500 to 570 nm, and a point corresponding to a wavelength of 535 nm on the “virtual line a” is a point A; a “virtual line b” parallel to wavelength axis passes through an average value of a maximum reflectance and a minimum reflectance of the reflection spectrum at a wavelength of 620 to 780 nm, and a point corresponding to a wavelength of 700 nm on the “virtual line b” is a point B; and a straight line passing through the point A and the point B that is extended to a wavelength of 500 to 780 nm is a reference line AB, (1) when comparing a reflectance value of the reflection spectrum and a reflectance value of the reference line AB at a wavelength of 500 to 570 nm, an absolute value of a difference in reflectance value between the reflection spectrum and the reference line AB at a wavelength where the difference in reflectance value between the reflection spectrum and the reference line AB is maximized was obtained as a maximum variation difference Δ A expressed by percentage of reflectance, and (2) when comparing a reflectance value of the reflection spectrum and a reflectance value of the reference line AB at a wavelength of 620 to 780 nm, an absolute value of a difference in reflectance value between the reflection spectrum and the reference line AB at a wavelength where the difference in reflectance value between the reflection spectrum and the reference line AB is maximized was obtained as a maximum variation difference Δ B expressed by percentage of reflectance.

Visible Light Transmittance

Visible light transmittance was measured in a range of 380 to 780 nm by using a UV-Vis-NIR spectrophotometer “Ubest V-570 type” (trade name, manufactured by JASCO Corporation), with the glass substrate side being set as the light-entering side, and the visible light transmittance was calculated based on JIS A5759.

Haze

Haze value was measured based on JIS K7136 by using a haze meter NDH-2000 (trade name, manufactured by Nippon Denshoku Industries Co., Ltd.) with the glass substrate side being set as the light-entering side.

Normal Emissivity

Normal emissivity was obtained based on JIS R3106 by attaching an attachment for regular reflectance measurement to an infrared spectrophotometer “IR Prestige 21” (trade name, manufactured by Shimadzu Corporation) and measuring a spectral reflectance at a wavelength of 5 to 25.2 μm on the protective layer side surface of an infrared reflective film. In the calculation of the normal emissivity, a value of the spectral reflectance at a wavelength of 25.2 μm was applied to the spectral reflectance at a wavelength of 25.2 to 50 μm.

Shading Coefficient

The shading coefficient was obtained from the values of solar transmittance, solar reflectance and normal emissivity, the solar transmittance and the solar reflectance being obtained according to JIS A5759 and the normal emissivity being obtained according to JIS R3106 based on spectral transmittance and spectral reflectance measured in a range of 300 to 2500 nm by using the aforementioned UV-Vis-NIR spectrophotometer “Ubest V-570 type” with the glass substrate side being set as the light-entering side.

Heat Transmission Coefficient

The heat transmission coefficient of an infrared reflective film was obtained according to JIS A5759 based on the normal emissivity of the protective layer side surface and the glass substrate side surface of an infrared reflective film determined according to JIS R3106 based on the spectral reflectance of the protective layer side surface and the glass substrate side surface of the infrared reflective film measured in a range of 5.5 to 25.2 μm by attaching an attachment for regular reflectance measurement to the aforementioned infrared spectrophotometer “IR Prestige 21”.

Initial Adhesion

A grid tape separation test according to JIS D0202-1998 was performed on the protective layer side surface of an infrared reflective film. To be specific, adhesion was evaluated by applying a cellophane tape “CT24” (trade name, manufactured by Nichiban Co., Ltd) in close contact to the protective layer by using the pad of the finger and thereafter peeling off the tape therefrom. Evaluation was made by the number of grid squares remaining without being taken away among 100 grid squares, and a rating of 100/100 was given if the protective layer was not taken away at all, and a rating of 0/100 was given if the protective layer was completely taken away.

Adhesion after Weather Resistance Test

A weather resistance test according to JIS A5759 was performed in which an infrared reflective film was irradiated with a sunshine carbon arc lamp for 1000 hours, and thereafter adhesion was evaluated in the same manner as the initial adhesion described above.

Scratch Resistance

A commercially available white flannel cloth was placed on the protective layer of an infrared reflective film, and then moved back and forth 1000 times under a load of 1000 g/cm². After that, the surface condition of the protective layer was visually observed and evaluated based on the following three criteria:

A: no scratches were found;

B: a few (5 or less) scratches were found; and

C: a large number (6 or more) of scratches were found.

Corrosion Resistance

A corrosion resistance test in which an infrared reflective film was allowed to stand under an environment of 50° C. and relative humidity of 90% for 168 hours, and thereafter the corrosion resistance of an infrared reflective film was visually observed and evaluated based on the following three criteria:

A: a progress of corrosion was not found over the whole of the infrared reflective film;

B: a corrosion of 1 mm or less was found at a part of the edge of the infrared reflective film; and

C: a corrosion of more than 1 mm was found at a part of the edge of the infrared reflective film.

Appearance (Iridescent property)

The appearance of an infrared reflective film was visually observed from the protective layer side under a three-wavelength fluorescent lamp, and evaluated based on the following three criteria:

A: an iridescent pattern was almost not found, and color non-uniformity by reflection was almost not recognized;

B: an iridescent pattern was slightly found, and color non-uniformity by reflection was slightly recognized; and

C: an iridescent pattern was clearly found, and color non-uniformity by reflection was clearly recognized.

Appearance (Angle Dependence)

The appearance of an infrared reflective film was visually observed from the protective layer side under a three-wavelength fluorescent lamp, and the state of reflection color observed from the front and that from a different angle were evaluated based on the following three criteria:

A: the difference in reflection color between when observed from the front and when observed from a different angle was almost not seen as a color change;

B: the difference in reflection color between when observed from the front and when observed from a different angle was slightly seen as a color change; and

C: the difference in reflection color between when observed from the front and when observed from a different angle was clearly seen as a color change.

The above results are shown in Tables 1 to 10 together with the layer configurations of the transparent heat-shielding/heat-insulating members.

TABLE 1

| | | Ex. 1 | Ex. 2 | Ex. 3 | Ex. 4 | Ex. 5 |
|---|---|---|---|---|---|---|
| Layer | Low refractive | Low refractive index | Low refractive index | Low refractive index | Low refractive index | Low refractive index |
| config- | index layer | coating material A | coating material A | coating material A | coating material A | coating material A |
| uration | | Thickness: 100 nm | Thickness: 110 nm | Thickness: 110 nm | Thickness: 110 nm | Thickness: 100 nm |
| | | Refractive index: 1.38 | Refractive index: 1.38 | Refractive index: 1.38 | Refractive index: 1.38 | Refractive index: 1.38 |
| | High refractive | High refractive index | High refractive index | High refractive index | High refractive index | High refractive index |
| | index layer | coating material A | coating material A | coating material A | coating material A | coating material A |
| | | Thickness: 270 nm | Thickness: 80 nm | Thickness: 400 nm | Thickness: 240 nm | Thickness: 270 nm |
| | | Refractive index: 1.80 | Refractive index: 1.80 | Refractive index: 1.80 | Refractive index: 1.80 | Refractive index: 1.80 |
| | Medium refractive | Medium refractive | Medium refractive | Medium refractive | — | Medium refractive |
| | index layer | index coating | index coating | index coating | | index coating |
| | | material A | material A | material A | | material A |
| | | Thickness: 80 nm | Thickness: 60 nm | Thickness: 100 nm | | Thickness: 80 nm |
| | | Refractive index: 1.52 | Refractive index: 1.52 | Refractive index: 1.52 | | Refractive index: 1.52 |
| | Optical adjustment | Optical adjustment | Optical adjustment | Optical adjustment | — | Optical adjustment |
| | layer | coating material A | coating material A | coating material A | | coating material A |
| | | Thickness: 40 nm | Thickness: 60 nm | Thickness: 60 nm | | Thickness: 40 nm |
| | | Refractive index: 1.80 | Refractive index: 1.80 | Refractive index: 1.80 | | Refractive index: 1.80 |
| | Infrared reflective | TiOₓ layer: 2 nm | TiOₓ layer: 2 nm | TiOₓ layer: 2 nm | TiOₓ layer: 2 nm | TiOₓ layer: 2 nm |
| | layer | Ag layer: 10 nm | Ag layer: 10 nm | Ag layer: 10 nm | Ag layer: 10 nm | Ag layer: 10 nm |
| | | TiOₓ layer: 2 nm | TiOₓ layer: 2 nm | TiOₓ layer: 2 nm | TiOₓ layer: 2 nm | TiOₓ layer: 2 nm |
| | Thickness of | 490 nm | 310 nm | 670 nm | 350 nm | 490 nm |
| | protective layer | | | | | |
| | Transparent | PET film | PET film | PET film | PET film | PET film |
| | substrate | | | | | |
| | Cholesteric liquid | — | — | — | — | Thickness: 3 μm |
| | crystal polymer | | | | | |
| | layer | | | | | |
| | Pressure-sensitive | Thickness: 25 μm | Thickness: 25 μm | Thickness: 25 μm | Thickness: 25 μm | Thickness: 25 μm |
| | adhesive layer | | | | | |
| | Glass substrate | Thickness: 3 mm | Thickness: 3 mm | Thickness: 3 mm | Thickness: 3 mm | Thickness: 3 mm |

TABLE 2

| | Ex. 1 | Ex. 2 | Ex. 3 | Ex. 4 | Ex. 5 |
|---|---|---|---|---|---|
| Maximum variation | 5.0 | 2.0 | 7.0 | 2.0 | 5.0 |
| difference in | | | | | |
| reflectance ΔA (%) | | | | | |
| Maximum variation | 4.0 | 2.5 | 5.0 | 4.0 | 4.0 |
| difference in | | | | | |
| reflectance ΔB (%) | | | | | |
| Visible light | 75.8 | 75.0 | 74.9 | 67.1 | 76.6 |
| transmittance (%) | | | | | |
| Haze (%) | 0.69 | 0.67 | 0.71 | 0.68 | 0.70 |
| Normal emissivity | 0.14 | 0.13 | 0.17 | 0.13 | 0.14 |
| Shading coefficient | 0.61 | 0.61 | 0.61 | 0.59 | 0.59 |
| Heat transmission | 3.9 | 3.9 | 4.0 | 3.9 | 3.9 |
| coefficient | | | | | |
| (W/m² · K) | | | | | |
| Initial adhesion | 100/100 | 100/100 | 100/100 | 100/100 | 100/100 |
| Adhesion after | 100/100 | 100/100 | 100/100 | 100/100 | 100/100 |
| weather resistance | | | | | |
| test | | | | | |
| Scratch resistance | A | A | A | A | A |
| Corrosion resistance | A | A | A | A | A |
| Appearance | A | A | B | A | A |
| (Iridescent property) | | | | | |
| Appearance | A | A | B | A | A |
| (Angle dependence) | | | | | |

TABLE 3

| | | Ex. 6 | Ex. 7 | Ex. 8 | Ex. 9 | Ex. 10 |
|---|---|---|---|---|---|---|
| Layer | Low refractive | Low refractive index | Low refractive index | Low refractive index | Low refractive index | Low refractive index |
| config- | index layer | coating material A | coating material A | coating material A | coating material A | coating material A |
| uration | | Thickness: 100 nm | Thickness: 100 nm | Thickness: 100 nm | Thickness: 95 nm | Thickness: 110 nm |
| | | Refractive index: 1.38 | Refractive index: 1.38 | Refractive index: 1.38 | Refractive index: 1.38 | Refractive index: 1.38 |
| | High refractive | High refractive index | High refractive index | High refractive index | High refractive index | High refractive index |
| | index layer | coating material A | coating material A | coating material A | coating material A | coating material A |
| | | Thickness: 270 nm | Thickness: 270 nm | Thickness: 500 nm | Thickness: 65 nm | Thickness: 100 nm |
| | | Refractive index: 1.80 | Refractive index: 1.80 | Refractive index: 1.80 | Refractive index: 1.80 | Refractive index: 1.80 |
| | Medium refractive | Medium refractive | Medium refractive | Medium refractive | Medium refractive | — |
| | index layer | index coating | index coating | index coating | index coating | |
| | | material A | material B | material A | material A | |
| | | Thickness: 80 nm | Thickness: 130 nm | Thickness: 130 nm | Thickness: 55 nm | |
| | | Refractive index: 1.52 | Refractive index: 1.50 | Refractive index: 1.52 | Refractive index: 1.52 | |
| | Optical adjustment | Optical adjustment | — | Optical adjustment | Optical adjustment | — |
| | layer | coating material A | | coating material A | coating material A | |
| | | Thickness: 40 nm | | Thickness: 50 nm | Thickness: 50 nm | |
| | | Refractive index: 1.80 | | Refractive index: 1.80 | Refractive index: 1.80 | |
| | Infrared reflective | TiOₓ layer: 2 nm | TiOₓ layer: 2 nm | TiOₓ layer: 2 nm | TiOₓ layer: 2 nm | TiOₓ layer: 2 nm |
| | layer | Ag layer: 10 nm | Ag layer: 10 nm | Ag layer: 10 nm | Ag layer: 8 nm | Ag layer: 10 nm |
| | | TiO₂ layer: 2 nm | TiOₓ layer: 2 nm | TiOₓ layer: 2 nm | TiOₓ layer: 2 nm | TiOₓ layer: 2 nm |
| | Thickness of | 490 nm | 500 nm | 780 nm | 265 nm | 210 nm |
| | protective layer | | | | | |
| | Transparent | PET film | PET film | PET film | PET film | PET film |
| | substrate | | | | | |
| | Cholesteric liquid | — | — | — | — | — |
| | crystal polymer | | | | | |
| | layer | | | | | |
| | Pressure-sensitive | Thickness: 25 μm | Thickness: 25 μm | Thickness: 25 μm | Thickness: 25 μm | Thickness: 25 μm |
| | adhesive layer | | | | | |
| | Glass substrate | Thickness: 3 mm | Thickness: 3 mm | Thickness: 3 mm | Thickness: 3 mm | Thickness: 3 mm |

TABLE 4

| | Ex. 6 | Ex. 7 | Ex. 8 | Ex. 9 | Ex. 10 |
|---|---|---|---|---|---|
| Maximum variation | 5.5 | 2.0 | 4.0 | 3.0 | 4.5 |
| difference in | | | | | |
| reflectance ΔA (%) | | | | | |
| Maximum variation | 4.5 | 5.0 | 3.5 | 3.0 | 2.0 |
| difference in | | | | | |
| reflectance ΔB (%) | | | | | |
| Visible light | 73.0 | 71.3 | 74.7 | 71.0 | 68.4 |
| transmittance (%) | | | | | |
| Haze (%) | 0.61 | 0.67 | 0.67 | 0.60 | 0.60 |
| Normal emissivity | 0.14 | 0.14 | 0.20 | 0.13 | 0.11 |
| Shading coefficient | 0.60 | 0.58 | 0.61 | 0.64 | 0.62 |
| Heat transmission | 3.9 | 3.9 | 4.1 | 3.9 | 3.8 |
| coefficient | | | | | |
| (W/m² · K) | | | | | |
| Initial adhesion | 100/100 | 100/100 | 100/100 | 100/100 | 100/100 |
| Adhesion after | 100/100 | 91/100 | 100/100 | 100/100 | 100/100 |
| weather resistance | | | | | |
| test | | | | | |
| Scratch resistance | A | A | A | B | B |
| Corrosion resistance | B | A | A | A | A |
| Appearance | A | A | A | A | A |
| (Iridescent property) | | | | | |
| Appearance | A | A | A | A | A |
| (Angle dependence) | | | | | |

TABLE 5

| | | Ex. 11 | Ex. 12 | Ex. 13 | Ex. 14 | Ex. 15 |
|---|---|---|---|---|---|---|
| Layer | Low refractive | Low refractive index | Low refractive index | Low refractive index | Low refractive index | Low refractive index |
| config- | index layer | coating material A | coating material A | coating material A | coating material A | coating material B |
| uration | | Thickness: 100 nm | Thickness: 110 nm | Thickness: 115 nm | Thickness: 110 nm | Thickness: 100 nm |
| | | Refractive index: 1.38 | Refractive index: 1.38 | Refractive index: 1.38 | Refractive index: 1.38 | Refractive index: 1.45 |
| | High refractive | High refractive index | High refractive index | High refractive index | High refractive index | High refractive index |
| | index layer | coating material B | coating material C | coating material D | coating material A | coating material A |
| | | Thickness: 220 nm | Thickness: 80 nm | Thickness: 85 nm | Thickness: 320 nm | Thickness: 80 nm |
| | | Refractive index: 1.89 | Refractive index: 1.76 | Refractive index: 1.65 | Refractive index: 1.80 | Refractive index: 1.80 |
| | Medium refractive | Medium refractive | Medium refractive | Medium refractive | Medium refractive | Medium refractive |
| | index layer | index coating | index coating | index coating | index coating | index coating |
| | | material A | material A | material A | material A | material A |
| | | Thickness: 50 nm | Thickness: 60 nm | Thickness: 60 nm | Thickness: 100 nm | Thickness: 60 nm |
| | | Refractive index: 1.52 | Refractive index: 1.52 | Refractive index: 1.52 | Refractive index: 1.52 | Refractive index: 1.52 |
| | Optical adjustment | Optical adjustment | Optical adjustment | Optical adjustment | Optical adjustment | Optical adjustment |
| | layer | coating material B | coating material A | coating material B | coating material C | coating material A |
| | | Thickness: 76 nm | Thickness: 60 nm | Thickness: 55 nm | Thickness: 55 nm | Thickness: 60 nm |
| | | Refractive index: 1.89 | Refractive index: 1.80 | Refractive index: 1.89 | Refractive index: 1.60 | Refractive index: 1.80 |
| | Infrared reflective | TiOₓ layer: 2 nm | TiOₓ layer: 2 nm | TiOₓ layer: 2 nm | TiOₓ layer: 2 nm | TiOₓ layer: 2 nm |
| | layer | Ag layer: 10 nm | Ag layer: 10 nm | Ag layer: 10 nm | Ag layer: 8 nm | Ag layer: 10 nm |
| | | TiOₓ layer: 2 nm | TiOₓ layer: 2 nm | TiOₓ layer: 2 nm | TiOₓ layer: 2 nm | TiOₓ layer: 2 nm |
| | Thickness of | 446 nm | 310 nm | 315 nm | 585 nm | 300 nm |
| | protective layer | | | | | |
| | Transparent | PET film | PET film | PET film | PET film | PET film |
| | substrate | | | | | |
| | Cholesteric liquid | — | — | — | — | — |
| | crystal polymer | | | | | |
| | layer | | | | | |
| | Pressure-sensitive | Thickness: 25 μm | Thickness: 25 μm | Thickness: 25 μm | Thickness: 25 μm | Thickness: 25 μm |
| | adhesive layer | | | | | |
| | Glass substrate | Thickness: 3 mm | Thickness: 3 mm | Thickness: 3 mm | Thickness: 3 mm | Thickness: 3 mm |

TABLE 6

| | Ex. 11 | Ex. 12 | Ex. 13 | Ex. 14 | Ex. 15 |
|---|---|---|---|---|---|
| Maximum variation | 5.0 | 2.5 | 3.0 | 2.0 | 2.5 |
| difference in | | | | | |
| reflectance ΔA (%) | | | | | |
| Maximum variation | 6.0 | 3.0 | 2.5 | 4.0 | 3.5 |
| difference in | | | | | |
| reflectance ΔB (%) | | | | | |
| Visible light | 72.4 | 75.6 | 78.1 | 78.4 | 74.5 |
| transmittance (%) | | | | | |
| Haze (%) | 0.72 | 0.65 | 0.73 | 0.69 | 0.68 |
| Normal emissivity | 0.14 | 0.13 | 0.13 | 0.16 | 0.13 |
| Shading coefficient | 0.61 | 0.61 | 0.63 | 0.65 | 0.61 |
| Heat transmission | 3.9 | 3.9 | 3.9 | 4.0 | 3.9 |
| coefficient | | | | | |
| (W/m² · K) | | | | | |
| Initial adhesion | 100/100 | 100/100 | 100/100 | 100/100 | 100/100 |
| Adhesion after | 100/100 | 100/100 | 100/100 | 100/100 | 100/100 |
| weather resistance | | | | | |
| test | | | | | |
| Scratch resistance | A | A | A | A | A |
| Corrosion resistance | A | A | A | A | A |
| Appearance | B | A | A | A | A |
| (Iridescent property) | | | | | |
| Appearance | B | A | A | A | A |
| (Angle dependence) | | | | | |

TABLE 7

| | | Ex. 16 | Ex. 17 | Ex. 18 |
|---|---|---|---|---|
| Layer | Low refractive | Low refractive index | Low refractive index | Low refractive index |
| configuration | index layer | coating material A | coating material A | coating material A |
| | | Thickness: 120 nm | Thickness: 115 nm | Thickness: 100 nm |
| | | Refractive index: 1.38 | Refractive index: 1.38 | Refractive index: 1.38 |
| | High refractive | High refractive index | High refractive index | High refractive index |
| | index layer | coating material A | coating material A | coating material A |
| | | Thickness: 550 nm | Thickness: 505 nm | Thickness: 95 nm |
| | | Refractive index: 1.80 | Refractive index: 1.80 | Refractive index: 1.80 |
| | Medium refractive | Medium refractive | Medium refractive | Medium refractive |
| | index layer | index coating material A | index coating material A | index coating material A |
| | | Thickness: 200 nm | Thickness: 100 nm | Thickness: 90 nm |
| | | Refractive index: 1.52 | Refractive index: 1.52 | Refractive index: 1.52 |
| | Optical adjustment | Optical adjustment | Optical adjustment | Optical adjustment |
| | layer | coating material A | coating material A | coating material A |
| | | Thickness: 60 nm | Thickness: 80 nm | Thickness: 45 nm |
| | | Refractive index: 1.80 | Refractive index: 1.80 | Refractive index: 1.80 |
| | Infrared reflective | TiOₓ layer: 2 nm | TiOₓ layer: 6 nm | TiOₓ layer: 2 nm |
| | layer | Ag layer: 8 nm | Ag layer: 8 nm | Ag layer: 12 nm |
| | | TiOₓ layer: 2 nm | TiOₓ layer: 6 nm | TiOₓ layer: 2 nm |
| | Thickness of | 930 nm | 800 nm | 330 nm |
| | protective layer | | | |
| | Transparent | PET film | PET film | PET film |
| | substrate | | | |
| | Cholesteric liquid | — | — | — |
| | crystal polymer layer | | | |
| | Pressure-sensitive | Thickness: 25 μm | Thickness: 25 μm | Thickness: 25 μm |
| | adhesive layer | | | |
| | Glass substrate | Thickness: 3 mm | Thickness: 3 mm | Thickness: 3 mm |

TABLE 8

| | Ex. 16 | Ex. 17 | Ex. 18 |
|---|---|---|---|
| Maximum variation | 6.0 | 6.5 | 2.5 |
| difference in | | | |
| reflectance ΔA (%) | | | |
| Maximum variation | 4.5 | 4.5 | 3.0 |
| difference in | | | |
| reflectance ΔB (%) | | | |
| Visible light | 74.7 | 64.6 | 71.2 |
| transmittance (%) | | | |
| Haze (%) | 0.72 | 0.65 | 0.70 |
| Normal emissivity | 0.22 | 0.20 | 0.11 |
| Shading coefficient | 0.64 | 0.55 | 0.59 |
| Heat transmission | 4.2 | 4.1 | 3.8 |
| coefficient | | | |
| (W/m² · K) | | | |
| Initial adhesion | 100/100 | 100/100 | 100/100 |
| Adhesion after | 100/100 | 100/100 | 100/100 |
| weather resistance | | | |
| test | | | |
| Scratch resistance | A | A | A |
| Corrosion resistance | A | A | A |
| Appearance | B | B | A |
| (Iridescent property) | | | |
| Appearance | B | B | A |
| (Angle dependence) | | | |

TABLE 9

| | | Compar- | Compar- | Compar- | Compar- |
|---|---|---|---|---|---|
| | | ative | ative | ative | ative |
| | | Ex. 1 | Ex. 2 | Ex. 3 | Ex. 4 |
| Layer | Low refractive | — | — | Low refractive index | Low refractive index |
| configuration | index layer | | | coating material A | coating material A |
| | | | | Thickness: 110 nm | Thickness: 80 nm |
| | | | | Refractive index: 1.38 | Refractive index: 1.38 |
| | High refractive | — | — | High refractive index | — |
| | index layer | | | coating material A | |
| | | | | Thickness: 700 nm | |
| | | | | Refractive index: 1.80 | |
| | Medium refractive | Medium refractive index | Medium refractive index | Medium refractive index | — |
| | index layer | coating material C | coating material C | coating material A | |
| | | Thickness: 800 nm | Thickness: 3000 nm | Thickness: 150 nm | |
| | | Refractive index: 1.50 | Refractive index: 1.50 | Refractive index: 1.52 | |
| | Optical adjustment | — | Optical adjustment | Optical adjustment | — |
| | layer | | coating material A | coating material A | |
| | | | Thickness: 40 nm | Thickness: 50 nm | |
| | | | Refractive index: 1.80 | Refractive index: 1.80 | |
| | Infrared reflective | ITO layer: 30 nm | TiOₓ layer: 2 nm | TiOₓ layer: 2 nm | TiOₓ layer: 2 nm |
| | layer | Ag layer: 12 nm | Ag layer: 10 nm | Ag layer: 10 nm | Ag layer: 10 nm |
| | | ITO layer: 30 nm | TiOₓ layer: 2 nm | TiOₓ layer: 2 nm | TiOₓ layer: 2 nm |
| | Thickness of | 800 nm | 3040 nm | 1010 nm | 80 nm |
| | protective layer | | | | |
| | Transparent | PET film | PET film | PET film | PET film |
| | substrate | | | | |
| | Cholesteric liquid | — | — | — | — |
| | crystal polymer layer | | | | |
| | Pressure-sensitive | Thickness: 25 μm | Thickness: 25 μm | Thickness: 25 μm | Thickness: 25 μm |
| | adhesive layer | | | | |
| | Glass substrate | Thickness: 3 mm | Thickness: 3 mm | Thickness: 3 mm | Thickness: 3 mm |

TABLE 10

| | Compar- | Compar- | Compar- | Compar- |
|---|---|---|---|---|
| | ative | ative | ative | ative |
| | Ex. 1 | Ex. 2 | Ex. 3 | Ex. 4 |
| Maximum variation | 8.0 | 7.5 | 5.0 | 0.5 |
| difference in | | | | |
| reflectance ΔA (%) | | | | |
| Maximum variation | 13.0 | 9.5 | 3.5 | 1.0 |
| difference in | | | | |
| reflectance ΔB (%) | | | | |
| Visible light | 73.0 | 69.9 | 78.6 | 72.5 |
| transmittance (%) | | | | |
| Haze (%) | 0.64 | 0.65 | 0.79 | 0.63 |
| Normal emissivity | 0.14 | 0.31 | 0.24 | 0.11 |
| Shading coefficient | 0.58 | 0.61 | 0.65 | 0.58 |
| Heat transmission | 3.9 | 4.5 | 4.3 | 3.8 |
| coefficient | | | | |
| (W/m² · K) | | | | |
| Initial adhesion | 93/100 | 100/100 | 100/100 | 32/100 |
| Adhesion after | 72/100 | 100/100 | 100/100 | 10/100 |
| weather resistance | | | | |
| test | | | | |
| Scratch resistance | A | A | A | C |
| Corrosion resistance | C | A | A | B |
| Appearance | C | C | A | A |
| (Iridescent property) | | | | |
| Appearance | C | B | A | A |
| (Angle dependence) | | | | |

As shown in Tables 1 to 8, it can be seen that the transparent heat-shielding/heat-insulating members of Examples 1 to 18 exhibited small values of the maximum variation differences in reflectance Δ A and Δ B, which indicates that they are superior in terms of appearance such as a reflection color change caused by the iridescent phenomenon and the viewing angle. Also, it can be seen that the transparent heat-shielding/heat-insulating members exhibited low shading coefficients and low heat transmission coefficients, which indicates that they are superior in terms of both heat shielding properties in summer and heat insulation properties in winter, and are also superior in terms of scratch resistance and the adhesion of the protective layer. Among them, in terms of appearance, Examples 1, 2, 4 to 10, 12 to 15, and 18 are particularly excellent. Furthermore, Example 5 in which a cholesteric liquid crystal polymer layer was formed is slightly superior in terms of shading coefficient and visible light transmittance to Example 1 in which a cholesteric liquid crystal polymer layer was not formed. Examples 4 and 10 exhibited slightly low visible light transmittance because the protective layer had a two-layer structure where the optical adjustment layer and the medium refractive index layer were not included. Example 6 in which a TiO₂ layer was used for the metal oxide layer of the infrared reflective layer is slightly inferior in terms of stability of the thin silver film as a metal layer to Example 1, and also, in a corrosion resistance test, corrosion of a film was found at a part of the edges. Example 7 in which the protective layer had a three-layer structure where the optical adjustment layer was not included is slightly low in visible light transmittance, and is slightly inferior in terms of adhesion to the infrared reflective layer after the weather resistance test as compared to Examples 1 to 3, 5, 8, 11 to 13 and 15 which had the same infrared reflective layer configuration as that of Example 7. Examples 8, 16 and 17 in which each of the protective layers had the total thickness of 780 nm, 930 nm, and 800 nm respectively are slightly inferior in terms of heat insulation performance to Examples 1 to 7, 9 to 15 and 18, because the protective layers of Examples 8, 16 and 17 had the total thickness larger than those of Examples 1 to 7, 9 to 15 and 18, and each of the obtained infrared reflective films attained the normal emissivity of 0.20, 0.22, and 0.20 respectively. Examples 9 and 10 in which the protective layer had the total thickness of less than 300 nm are slightly inferior in terms of scratch resistance to Examples 1 to 8 and 11 to 18. Example 17 in which the metal suboxide layer had a large thickness of 6 nm is slightly low in visible light transmittance as compared to Examples 9, 14 and 16 in which the metal layer had the same thickness as that of Example 17.

On the other hand, as shown in Tables 9 to 10, the obtained infrared reflective film of Comparative Example 1 exhibited a large size of ripple in the obtained visible light reflection spectrum, because Comparative Example 1 had the protective layer having a mono-layer structure made of an urethane acrylate-based ionizing radiation curable resin. In the appearance of the obtained infrared reflective film of Comparative Example 1, since the values of the maximum variation differences in reflectance Δ A and Δ B were large, an iridescent pattern was clearly observed and when observed from different angles of reflected light, the reflection color changing between red and green was observed, and as a result of which the appearance was insufficient. Comparative Example 1 is also inferior in terms of corrosion resistance because ITO was used for the metal oxide layer of the infrared reflective layer.

The obtained infrared reflective film of Comparative Example 2 exhibited an increase in normal emissivity and heat transmission coefficient, and a significant decrease in heat insulation performance because Comparative Example 2 had the protective layer having a two-layer structure composed of the optical adjustment layer and the medium refractive index layer, wherein an urethane acrylate-based ionizing radiation curable resin, which has a large absorption of light in the infrared region, was used as a material of the medium refractive index layer and the medium refractive index layer had a thickness of 3000 nm. In the appearance of Comparative Example 2, since the size of ripple in the obtained reflection spectrum was large and the values of the maximum variation differences in reflectance Δ A and Δ B were also large, the iridescent pattern was observed.

Comparative Example 3 had the protective layer having a total thickness of 1010 nm, and the obtained infrared reflective film attained a normal emissivity of 0.24, and slightly low heat insulation performance is confirmed as compared to Examples 1 to 18.

In the appearance of Comparative Example 4 in which the protective layer was formed by providing only the low refractive index layer made of a 80 nm thin film on the infrared reflective layer exhibited no problem of appearance in terms of the iridescent pattern of the reflection color and angle dependence caused by the viewing angle. However, the adhesion between the infrared reflective layer and the low refractive index layer is poor, and separation of the protective layer was observed. Comparative Example 4 is also inferior in terms of scratch resistance because the thickness of the protective layer was extremely thick.

The present invention can provide a transparent heat-shielding/heat-insulating member having an excellent heat-shielding function and heat-insulating function, wherein excellent scratch resistance and adhesion of the protective layer can be achieved while high heat insulation properties are maintained, and a reflection color change in the appearance caused by the iridescent phenomenon and the viewing angle is small.

The present invention may be embodied in other forms without departing from the spirit or essential characteristics thereof. The embodiments disclosed in this application are to be considered in all respects as illustrative and not limiting. The scope of the present invention is indicated by the appended claims rather than by the foregoing description, and all changes which come within the meaning and range of equivalency of the claims are intended to be embraced therein.

What is claimed is:

1. A transparent heat-shielding/heat-insulating member comprising a transparent substrate and a functional layer formed on the transparent substrate,
wherein the functional layer includes, from the transparent substrate side, an infrared reflective layer and a protective layer in this order,
the infrared reflective layer includes, from the transparent substrate side, at least a metal layer, and a metal suboxide layer in which a metal is partially oxidized, in this order,
the protective layer has a total thickness of 200 to 980 nm, and includes, from the infrared reflective layer side, at least a high refractive index layer and a low refractive index layer in this order.

2. The transparent heat-shielding/heat-insulating member according to claim 1,
wherein the metal suboxide layer in which a metal is partially oxidized has a thickness of 1 to 8 nm.

3. The transparent heat-shielding/heat-insulating member according to claim 1,
wherein the protective layer includes, from the infrared reflective layer side, a medium refractive index layer, a high refractive index layer and a low refractive index layer in this order.

4. The transparent heat-shielding/heat-insulating member according to claim 1,
wherein the protective layer includes, from the infrared reflective layer side, an optical adjustment layer, a medium refractive index layer, a high refractive index layer and a low refractive index layer in this order,
the optical adjustment layer has a refractive index at a wavelength of 550 nm of 1.60 to 2.00 and a thickness of 30 to 80 nm,
the medium refractive index layer has a refractive index at a wavelength of 550 nm of 1.45 to 1.55 and a thickness of 40 to 200 nm,
the high refractive index layer has a refractive index at a wavelength of 550 nm of 1.65 to 1.95 and a thickness of 60 to 550 nm, and
the low refractive index layer has a refractive index at a wavelength of 550 nm of 1.30 to 1.45 and a thickness of 70 to 150 nm.

5. The transparent heat-shielding/heat-insulating member according to claim 1,
wherein the metal suboxide layer in which a metal is partially oxidized includes a titanium component.

6. The transparent heat-shielding/heat-insulating member according to claim 1,
wherein a layer of the protective layer in contact with the infrared reflective layer includes titanium oxide fine particles.

7. The transparent heat-shielding/heat-insulating member according to claim 1,
wherein the metal layer of the infrared reflective layer includes silver and has a thickness of 3 to 20 nm.

8. The transparent heat-shielding/heat-insulating member according to claim 1,
wherein a cholesteric liquid crystal polymer layer is further formed on a surface of the transparent substrate on which the infrared reflective layer is not formed.

9. The transparent heat-shielding/heat-insulating member according to claim 8,
wherein the cholesteric liquid crystal polymer layer is formed by photopolymerization of a material containing a liquid crystal compound having a polymerizable functional group, a chiral agent having a polymerizable functional group and a multifunctional acrylate compound.

10. The transparent heat-shielding/heat-insulating member according to claim 1,
wherein in a reflection spectrum measured according to JIS R3106-1998,
if a “virtual line a” parallel to wavelength axis passes through an average value of a maximum reflectance and a minimum reflectance of the reflection spectrum at a wavelength of 500 to 570 nm, and a point corresponding to a wavelength of 535 nm on the “virtual line a” is a point A;
a “virtual line b” parallel to wavelength axis passes through an average value of a maximum reflectance and a minimum reflectance of the reflection spectrum at a wavelength of 620 to 780 nm, and a point corresponding to a wavelength of 700 nm on the “virtual line b” is a point B; and
a straight line passing through the point A and the point B that is extended to a wavelength of 500 to 780 nm is a reference line AB,
when comparing a reflectance value of the reflection spectrum and a reflectance value of the reference line AB at a wavelength of 500 to 570 nm, if an absolute value of a difference in reflectance value between the reflection spectrum and the reference line AB at a wavelength where the difference in reflectance value between the reflection spectrum and the reference line AB is maximized is defined as a maximum variation difference Δ A, a value of the maximum variation difference Δ A expressed by percentage of reflectance is 7% or less, and
when comparing a reflectance value of the reflection spectrum and a reflectance value of the reference line AB at a wavelength of 620 to 780 nm, if an absolute value of a difference in reflectance value between the reflection spectrum and the reference line AB at a wavelength where the difference in reflectance value between the reflection spectrum and the reference line AB is maximized is defined as a maximum variation difference Δ B, a value of the maximum variation difference Δ B expressed by percentage of reflectance is 9% or less.

11. The transparent heat-shielding/heat-insulating member according to claim 1,
wherein a normal emissivity based on JIS R3106-1998 is 0.22 or less on the functional layer side.

12. The transparent heat-shielding/heat-insulating member according to claim 1,
wherein after a 1000-hour weather resistance test according to JIS A5759, separation of the protective layer is not observed in a cross cut adhesion test according to JIS D0202-1998.

13. A method for producing the transparent heat-shielding/heat-insulating member according to claim 1, the method comprising:
forming an infrared reflective layer on a transparent substrate by a dry coating method; and
forming a protective layer on the infrared reflective layer by a wet coating method.

14. The method for producing the transparent heat-shielding/heat-insulating member according to claim 13,
wherein the dry coating method is a reactive spattering method.
